(19) United States
(12) Patent Application Publication
(10) Pub. No.: US 2026/0305090 A1
(43) Pub. Date: Oct. 1, 2026

(54) IMAGE DISPLAY DEVICE AND SMARTPHONE

(71) Applicant: NICHIA CORPORATION, Anan-shi, Tokushima (JP)

(72) Inventor: Saiki YAMAMOTO, Tokushima-shi (JP)

(73) Assignee: NICHIA CORPORATION, Anan-shi, Tokushima (JP)

(21) Appl. No.: 19/477,614

(22) PCT Filed: Apr. 18, 2024
(86) PCT No.: PCT/JP2024/015472

§ 371 Date: Oct. 22, 2025

(30) Foreign Application Priority Data
Apr. 27, 2023 (JP) 2023-072912

(51) Int. Cl. H10K 59/131; H10K 59/38; H10K 59/40; H10K 59/80; H10K 59/90

(52) U.S. Cl. CPC H10K 59/131; H10K 59/38; H10K 59/40; H10K 59/879; H10K 59/90

(57) ABSTRACT

An image display device includes: a housing having inner lateral surfaces and an opening defined by the inner lateral surfaces; a display unit disposed in the opening and located on an inner side relative to the inner lateral surfaces of the housing, the display unit including a display surface and a lateral surface connected to the display surface; one or more wiring substrates, each disposed on a corresponding one of the inner lateral surfaces of the housing and including wiring portions at least on a side opposite to a surface thereof facing the corresponding inner lateral surface; and one or more light emitting parts, each disposed between a corresponding one of the inner lateral surfaces of the housing and a corresponding one of the lateral surfaces of the display unit and each disposed on corresponding ones of the wiring portions.

### CROSS-REFERENCE TO RELATED APPLICATIONS

This is a U.S. National Stage Application of PCT Application No. PCT/JP2024/015472, filed Apr. 18, 2024, which claims priority to Japanese Patent Application No. 2023-072912, filed Apr. 27, 2023. The entire contents of these applications are incorporated by reference herein.

### BACKGROUND

### Technical Field

The present disclosure relates to an image display device and a smartphone.

### Background Art

In the related art, an image display device has been disclosed, in which a light emitting part is provided between a screen module and a housing and mounted on an inner lateral surface of the housing, and a light guide member can guide light from the light emitting part in a direction in which a display surface of a display unit faces. See, for example, Chinese Patent Application Publication No. 111711770 (“Patent Document 1”).

### SUMMARY

However, in the image display device in Patent Document 1, the light emitting part and the light guide member are provided separately, and the light guide member needs to have a recess for accommodating the light emitting part. This increases the degree of technical difficulty to accurately accommodate the light emitting part in the recessed portion of the light guide member. Accordingly, assembly of the image display device may take time and labor and productivity may be reduced.

It is an object of embodiments according to the present disclosure to provide an image display device that can be assembled easily.

An image display device according to an embodiment of the present disclosure includes: a housing having inner lateral surfaces and an opening defined by the inner lateral surfaces; a display unit disposed in the opening and located on an inner side relative to the inner lateral surfaces of the housing, the display unit including a display surface and a lateral surface connected to the display surface; one or more wiring substrates, each disposed on a corresponding one of the inner lateral surfaces of the housing and including wiring portions at least on a side opposite to a surface thereof facing the corresponding inner lateral surface; and one or more light emitting parts, each disposed between a corresponding one of the inner lateral surfaces of the housing and a corresponding one of the lateral surfaces of the display unit and each disposed on corresponding ones of the wiring portions. Each of the one or more light emitting parts includes: a mounting surface facing the wiring portions of the corresponding wiring substrate, and a light emission surface meeting and connected to the mounting surface. The one or more light emitting parts are configured to emit light in a direction in which the display surface faces.

According to embodiments of the present disclosure, an image display device that can be assembled easily can be provided.

### BRIEF DESCRIPTION OF THE DRAWINGS

FIG. 1 is a schematic plan view illustrating an image display device according to a first embodiment

FIG. 2 is an exploded perspective view including a housing and a display unit of the image display device according to the first embodiment

FIG. 3A is a perspective view of the housing of the image display device according to the first embodiment

FIG. 3B illustrates a first example of a wiring substrate according to the first embodiment.

FIG. 3C is a circuit diagram illustrating a light emitting part in the first example of the wiring substrate according to the first embodiment

FIG. 3D illustrates a second example of the wiring substrate according to the first embodiment

FIG. 3E is a circuit diagram illustrating a light emitting part in the second example of the wiring substrate according to the first embodiment

FIG. 4 is a perspective view illustrating an inner lateral surface of the image display device according to the first embodiment

FIG. 5 is an enlarged view of an area of and around the wiring substrate of the image display device according to the first embodiment

FIG. 6 is an enlarged view of an area of and around the light emitting part of the image display device according to the first embodiment

FIG. 7 is an exploded perspective view of a portion including the light emitting part and a wiring portion of the image display device according to the first embodiment, when viewed from the light emitting part side toward the wiring portion

FIG. 8 is a perspective view of the light emitting part according to the first embodiment

FIG. 9 is a cross-sectional view including a normal line of a light emission surface of the light emitting part, and taken along a mounting surface according to the first embodiment

FIG. 10A is a cross-sectional view including the normal line of the light emission surface of the light emitting part, and intersecting the mounting surface according to the first embodiment

FIG. 10B is a schematic plan view illustrating an image display device according to a variation of the first embodiment

FIG. 11 is a schematic plan view of an image display device according to a second embodiment

FIG. 12 is a perspective view of a first example of a first light source structure according to the second embodiment

FIG. 13 is a cross-sectional view including a normal line of a light emission surface in the first example of the first light source structure according to the second embodiment, and taken along a mounting surface

FIG. 14A is a cross-sectional view including the normal line of the light emission surface in the first example of the first light source structure according to the second embodiment, and intersecting the mounting surface

FIG. 14B is a perspective view of a second example of the first light source structure according to the second embodiment

FIG. 14C is a cross-sectional view including the normal line of the light emission surface in the second example of the first light source structure according to the second embodiment, and taken along the mounting surface

FIG. 14D is a cross-sectional view including the normal line of the light emission surface in the second example of the first light source structure according to the second embodiment, and intersecting the mounting surface

FIG. 15 is a perspective view of a second light source structure according to the second embodiment

FIG. 16 is a cross-sectional view including a normal line of a light emission surface of the second light source structure according to the second embodiment, and taken along a mounting surface

FIG. 17 is a cross-sectional view including the normal line of the light emission surface of the second light source structure according to the second embodiment, and intersecting the mounting surface

FIG. 18 schematically illustrates light distribution characteristics of the first light source structure according to the second embodiment

FIG. 19 schematically illustrates light distribution characteristics of the second light source structure according to the second embodiment

FIG. 20A illustrates an example of the simulation result of an illuminance distribution of irradiation light of the first light source structure in which a first lens is not provided

FIG. 20B illustrates an example of the simulation result of an illuminance distribution of irradiation light of the second light source structure in which a second lens is not provided

FIG. 21A illustrates an example of the simulation result of an illuminance distribution of irradiation light of the first light source structure in which the first lens is provided

FIG. 21B illustrates an example of the simulation result of an illuminance distribution of irradiation light of the second light source structure in which the second lens is provided

FIG. 22 schematically illustrates the irradiation light obtained by combining first irradiation light from each of a plurality of first light source structures and second irradiation light from each of a plurality of second light source structures in the image display device according to the second embodiment

FIG. 23 illustrates a configuration example in which a light source structure is disposed on a curved surface of a housing.

### DETAILED DESCRIPTION

Image display devices according to embodiments of the present disclosure will be described in detail with reference to the accompanying drawings. The modes illustrated below are described as examples of the image display device to embody the technical idea of the present disclosure, and are not limited to the following. Dimensions, materials, shapes, relative arrangements, or the like of constituent members described in the embodiments are not intended to limit the scope of the present disclosure thereto, unless otherwise specified, and are merely examples. Note that the sizes, positional relationship, or the like of members illustrated in the drawings may be exaggerated for clarity of description. In the following description, members having the same terms and reference characters represent the same members or members of the same type, and a detailed description of these members is omitted as appropriate. As a cross-sectional view, an end view illustrating only a cut surface may be used.

In the following embodiments, the phrase “being along a certain direction” includes an object having an inclination within a range of ±10°with respect to the certain direction.

The phrase “being along a plane” includes an object having an inclination within a range of ±10 ° with respect to the plane. In the embodiments, being orthogonal and at a right angle may include a deviation within ±10° with respect to 90°. A plan view refers to viewing an object in a direction normal to the light emission surface of the light-emitting part of the image display device according to the embodiments. From another perspective, a plan view refers to viewing an object from a direction normal to the display surface of the display unit of the image display device according to the embodiments. An upper surface refers to viewing an object from the direction normal to the light emission surface of the light emitting part of the image display device according to the embodiments. A lower surface refers to viewing an object from a direction opposite to the direction normal to the light emission surface of the light emitting part of the image display device according to the embodiments.

In the present specification or the claims, polygons such as triangles and quadrangles, including shapes in which the corners of the polygon are rounded, beveled, chamfered, or coved, are referred to as polygons. Not only shapes modified at their corners (ends of a side) but also shapes modified at intermediate portions of their sides are also referred to as a polygon. That is, a polygon-based shape with partial modification is included in the interpretation of the “polygon” described in the present specification and the claims.

In the present specification or the claims, when there are a plurality of components and it is desired to denote those components individually, the components may be distinguished by adding terms such as “first,” “second,” and the like in front of terms of the components. Objects to be distinguished may differ between the present specification and the claims. Thus, even when a component in the claims is given the same term as that in the present specification, the object identified by that component is not the same across the present specification and the claims in some cases.

For example, when, in the present specification, there are components distinguished by being appended with “first,” “second,” and “third,” and in the present specification, and when components appended with “first” and “third” are to be described in the claims, or when components appended with “first” and components not appended with specific ordinal numbers are to be described in the claims, the components may be distinguished by being appended with “first” and “second” in the claims from the viewpoint of simplification. In this case, in the claims, components appended with “first,” and “second” respectively indicate components appended with “first,” and “third,” or components not appended with specific ordinal numbers in the present specification. This rule applies to not only components but also other objects in a reasonable and flexible manner.

Image display devices according to the embodiments are included in a smartphone as an example. The image display devices according to an embodiment display various images on the display unit, such as an operation image for operating the smartphone, an image displayed by executing an application program, and an image captured by an imaging device provided in the smartphone. The application program is a program installed in the smartphone, an external server communicably connected to the smartphone, or the like.

Examples of the imaging device provided in the smartphone include a camera for capturing still images, and a video camera for capturing moving images.

The image display devices according to the embodiments can display an image captured by an imaging device for selfies. Such an imaging device for selfies is disposed on a display surface side of a display unit of the image display device, and an operator who operates the image display device and the smartphone (hereinafter, referred to as an operator) photographs the operator himself/herself or a plurality of persons including the operator himself/herself. The imaging device for selfies is used in applications such as videophone, moving image capture, and personal authentication using smartphones.

### FIRST EMBODIMENT

### Configuration Example of Image Display Device 100

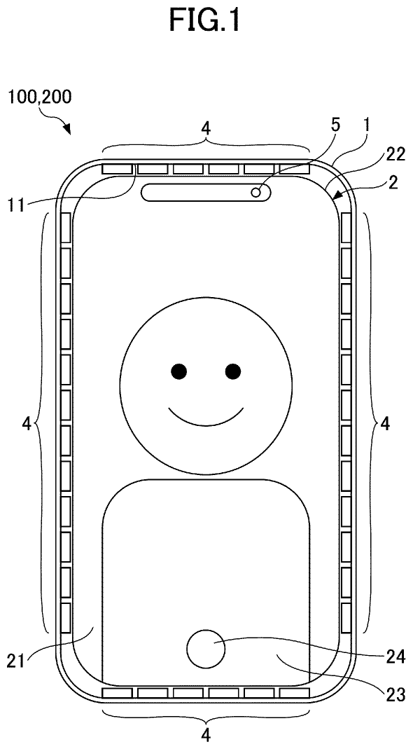

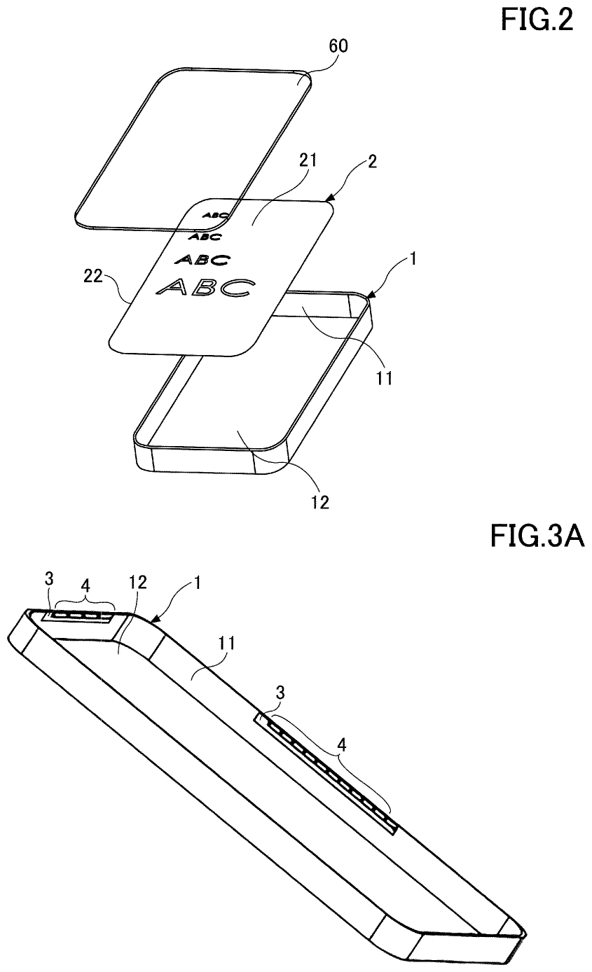

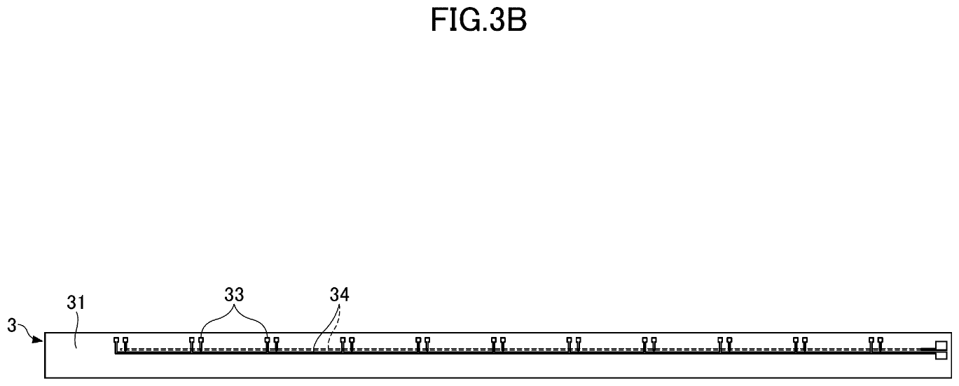

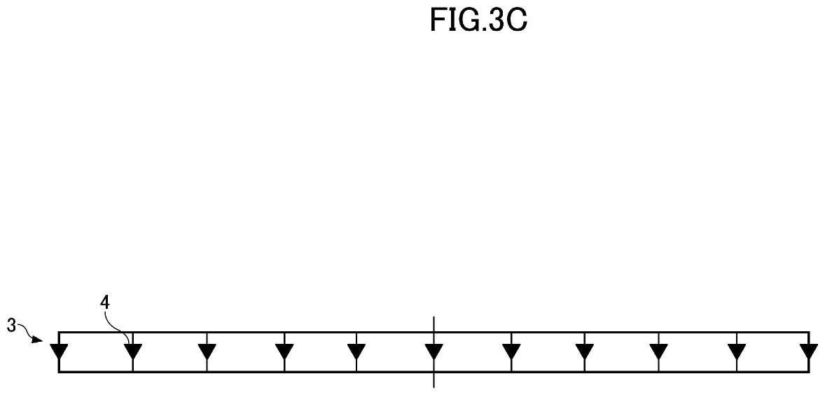

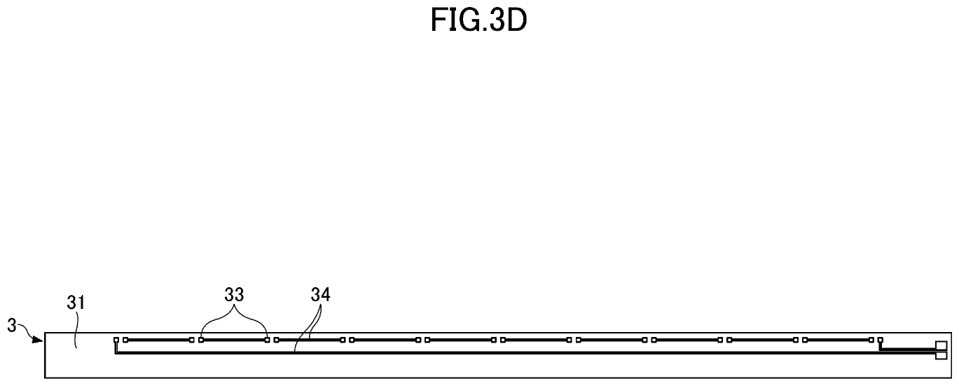

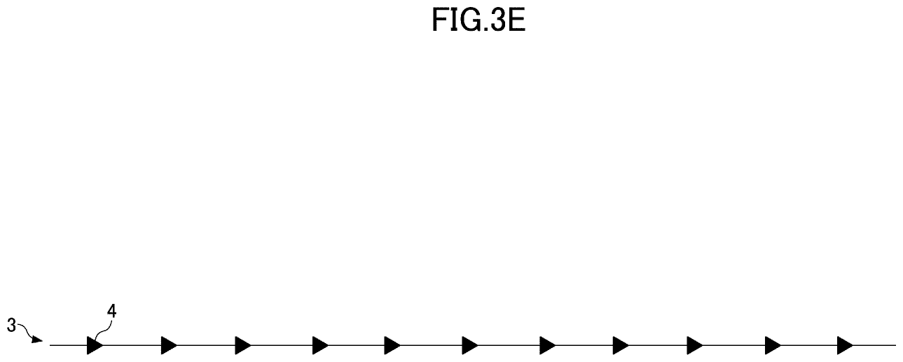

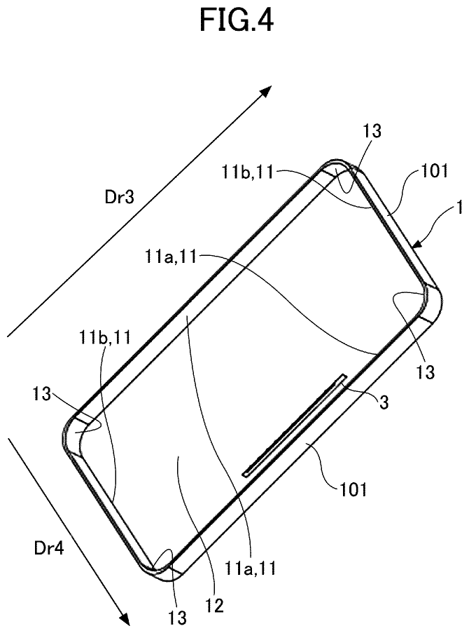

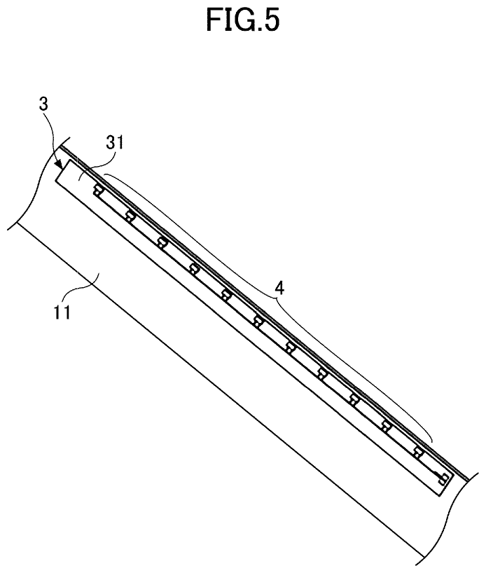

A configuration of an image display device 100 according to a first embodiment is described with reference to FIGS. 1 to 9. FIG. 1 is a schematic plan view of the image display device 100. FIG. 2 is an exploded perspective view including a housing 1 and a display unit 2 of the image display device 100. FIG. 3A is a perspective view of the housing 1 of the image display device 100. FIG. 3B illustrates a first wiring surface 31 in a first example of a wiring substrate 3 illustrated in FIG. 3A. FIG. 3C is a circuit diagram of a light emitting part 4 in the first example of the wiring substrate 3 illustrated in FIG. 3A. FIG. 3D illustrates a first wiring surface 31 in a second example of the wiring substrate 3 illustrated in FIG. 3A. FIG. 3E is a circuit diagram of the light emitting part 4 in the second example of the wiring substrate 3 illustrated in FIG. 3A. FIG. 4 is a perspective view illustrating an inner lateral surfaces 11 of the image display device 100. FIG. 5 is an enlarged view of the wiring substrate 3 and its vicinity illustrated in FIG. 3A in the image display device 100.

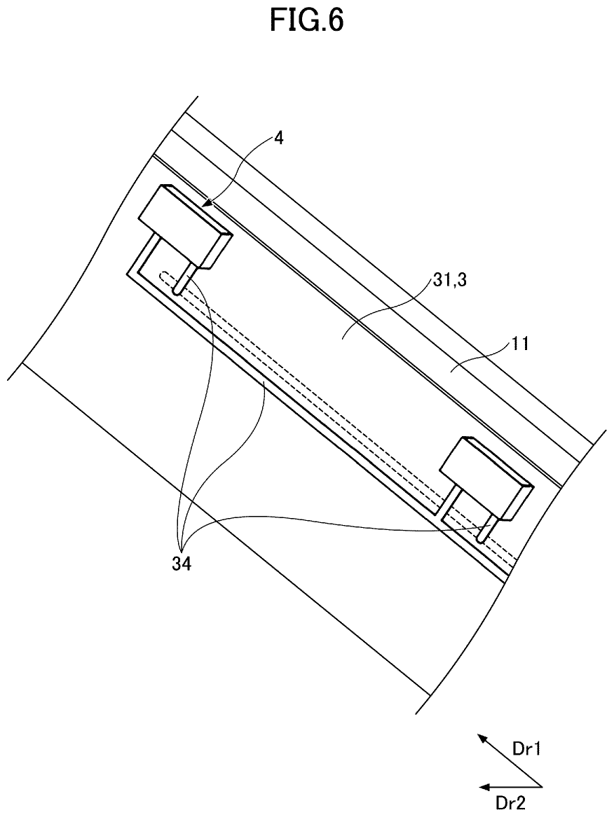

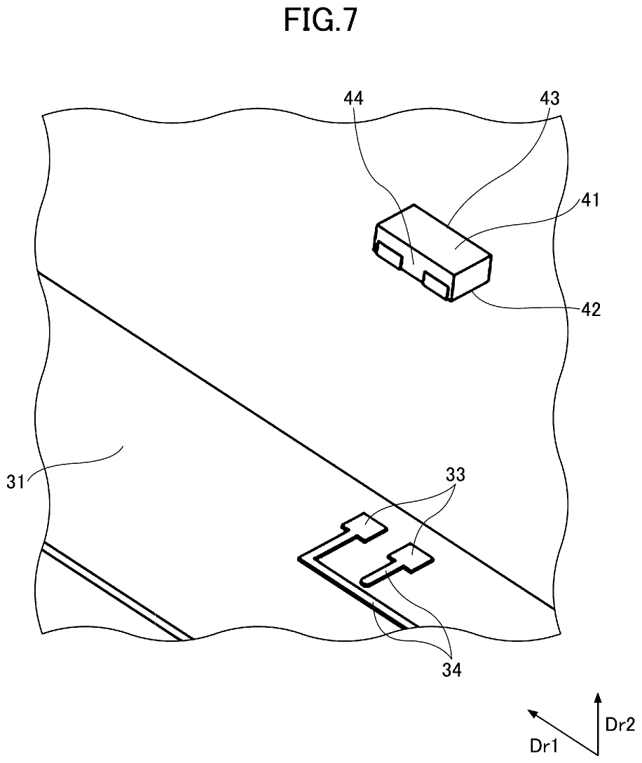

FIG. 6 is an enlarged view of and around the light emitting part 4 illustrated in FIG. 5 in the image display device 100. FIG. 7 is an exploded perspective view including the light emitting part 4 and the wiring portion 33 of the image display device 100 when the wiring portion is viewed from the light emitting part 4 side. FIG. 4 is an exploded perspective view of the image display device 100 including the light emitting part 4, the wiring substrate 3, and the housing 1 of the image display device 100, in which the wiring substrate 3 is partly omitted for the sake of explanation.

The image display device 100 according to the present embodiment includes the housing 1, the display unit 2, the wiring substrate 3, and one or more light emitting parts 4.

The image display device 100 is included in a smartphone 200.

As illustrated in FIGS. 1, 2, and 3A, the housing 1 has the inner lateral surfaces 11 and an opening 12 defined by the inner lateral surfaces 11. In the housing 1, outer lateral surfaces 101 are opposite to the inner lateral surfaces 11. The housing 1 is made of a material including a metal material, a resin material, or the like. From the viewpoint of increasing the strength and increasing the heat dissipation, the housing 1 is preferably made of a material including a metal material such as aluminum. As illustrated in FIG. 4, the inner lateral surfaces 11 of the housing 1 are in a substantially rectangular shape in a plan view and include a pair of long lateral surfaces 11a extending in a third direction Dr3 and a pair of short lateral surfaces 11b extending in a fourth direction Dr4 orthogonal to the third direction Dr3. The long lateral surfaces 11a are inner lateral surfaces longer than the short lateral surfaces 11b. In a plan view, the inner lateral surfaces 11 of the housing 1 may include a curved surface 13 between the long lateral surface 11a and the short lateral surface 11b.

As illustrated in FIG. 1, the display unit 2 is disposed in the opening portion 12 on an inner side relative to the inner lateral surfaces 11 of the housing 1. The display unit 2 has a display surface 21 and a lateral surface 22 connected to the display surface 21. The display unit 2 includes an organic electro luminescence (EL) panel, a liquid crystal panel, or the like. The display unit 2 displays an image on the display surface 21. The display unit 2 of the smartphone 200 has a touch panel function at the display surface 21.

In FIG. 1, the display unit 2 displays, on the display surface 21, a person image 23 captured by an imaging device 5 provided in the smartphone 200 and a capture button 24.

The imaging device 5 is an imaging device for selfies. The person image 23 is an image of an operator himself/herself captured by the imaging device 5.

The capture button 24 is an image displayed on the display surface 21 having the touch panel function. The capture button 24 is a user interface (UI) that functions as a button for causing the imaging device 5 to perform shooting when a touch operation is performed. For example, when the operator operates the image display device 100 and the smartphone 200 to take a selfie by the imaging device 5, the display surface 21 faces the operator. The operator can capture himself/herself or a plurality of persons including the operator himself/herself by the imaging device 5 by performing the touch operation on the capture button 24 while visually recognizing the image of the operator himself/herself or the plurality of persons including the operator himself/herself displayed on the display unit 2.

As illustrated in FIG. 2, the image display device 100 may include a cover plate 60 on the display unit 2. The cover plate 60 is made of a material including a resin material, a glass material, or the like having transmissivity. Preferably, the transmissivity herein refers to transmitting 60% or more of the light from the light emitting part 4. The image display device 100 includes the cover plate 60 on the display unit 2 to protect the display unit 2 from damage, dirt, or the like.

As illustrated in FIGS. 3A to 5, the wiring substrates 3 are disposed on the inner lateral surfaces 11 of the housing 1. As illustrated in FIG. 1, in the example described in the present specification, the wiring substrate 3 includes four wiring substrates 3 each arranged on a respective one of the four inner lateral surfaces 11 of the housing 1. The wiring substrates 3 are adhered onto the inner lateral surfaces 11 of the housing 1 using, for example, an adhesive member.

In the example illustrated in the present specification, the wiring portion 33 is disposed on one side of the wiring substrate 3. FIG. 3B illustrates the first example of the wiring substrate 3. As illustrated in FIG. 3B, in the wiring substrate 3 according to the first example, the wiring portion 33 is disposed on a first wiring surface 31, and wiring 34 is disposed on the first wiring surface 31 and a second wiring surface 32. As illustrated in FIG. 3C, in the wiring substrate 3 according to the first example, a plurality of light emitting parts 4 are connected in parallel. FIG. 3D illustrates a second example of the wiring substrate 3. As illustrated in FIG. 3D, in the wiring substrate 3 according to the second example, the wiring portion 33 and the wiring 34 are disposed on the first wiring surface 31, and the wiring 34 is not disposed on the second wiring surface 32. As illustrated in FIG. 3E, in the wiring substrate 3 according to the second example, the plurality of light emitting parts 4 are connected in series. The wiring 34 may be arranged on the wiring substrate 3 in such a manner that the wiring 34 is arranged on both sides of the wiring substrate 3. Alternatively, it may also be possible to provide both the wiring substrate 3 with the wiring 34 arranged on both sides and the wiring substrate 3 with the wiring 34 arranged on only one side.

As illustrated in FIGS. 6 and 7, the wiring substrate 3 has the wiring portion 33 at least on a side opposite to the second wiring surface 32, which is the surface facing the inner lateral surface 11. As illustrated in FIG. 7, the wiring portion 33 is disposed on the first wiring surface 31 which is a surface of the wiring substrate 3 located on the opposite side to the second wiring surface 32. The wiring portion 33 is made up of at least a pair of positive and negative electrodes for electrically connecting the wiring substrate 3 and the light emitting parts 4 which will be described later. For example, the wiring portion 33 includes an anode electrode and a cathode electrode. The wiring portion 33 of a corresponding one of the light emitting parts 4 may be electrically connected to the wiring portion 33 of an adjacent one of the light emitting parts 4 by the wiring 34. In FIGS. 3B and 6, to facilitate understanding, the wiring portion 33 and the wiring 34 which are seen through are indicated by dotted lines.

The wiring substrate 3 is a flexible substrate. The flexible substrate is made by, for example, bonding a base material and a conductive foil. Preferably, an insulating material is used for this base material. Specifically, the wiring substrate 3 can be made using polyimide resin, bismaleimide triazine (BT) resin, or other resins as the base material. A copper foil or the like can be used as the conductor foil. An adhesive member for bonding the base material and the conductor foil may be disposed between the base material and the conductor foil. The wiring substrate 3 is not limited to the flexible substrate.

As illustrated in FIG. 1, one or more light emitting parts 4 are disposed between the inner lateral surfaces 11 of the housing 1 and the lateral surfaces 22 of the display unit 2. In the example illustrated in FIGS. 1, 24 light emitting parts 4 are arranged on the pair of long lateral surfaces 11a (see FIG. 4) of the housing 1, that is, 12 light emitting parts 4 are arranged on one long lateral surface 11a. 12 light emitting parts 4 are disposed on the pair of short lateral surfaces 11b (see FIG. 4) of the housing 1, that is, six light emitting parts 4 are arranged on one short lateral surface 11b. The light emitting parts 4 are mounted on the wiring portions 33 with a bonding member such as solder so as to be electrically connected to the wiring substrate 3. In the present embodiment, the light emitting parts 4 are not disposed between the inner lateral surface 11 being the curved surface 13 of the housing 1 and the lateral surface 22 of the display unit 2.

As illustrated in FIGS. 3A to 7, one or more light emitting parts 4 are disposed on the wiring portions 33 individually. In the present embodiment, the one or more light emitting parts 4 include 36 light emitting parts 4. The 36 light emitting parts 4 are arranged in pairs on at least 36 pairs of positive and negative wiring portions 33 arranged on the first wiring surface 31.

Each of the 36 light emitting parts 4 includes at least one light-emitting element. The light-emitting elements can be controlled to be turned on individually or in groups. For example, the one or more light emitting parts 4 can be driven to light up by a driver integrated circuit (IC) or the like, in response to a control signal input from a controller or the like of the image display device 100, whereby a different electric current is diverted for each or a group of one or more light emitting parts 4 and supplied to the wiring substrate 3.

The driver IC may be one driver IC that can collectively drive each of the one or more light emitting parts 4 mounted on the one or more wiring substrates 3, or may be one driver IC that can collectively drive the one or more light emitting parts 4, which are mounted on the one wiring substrate 3, individually. Alternatively, the driver IC may include a plurality of drivers IC provided for the plurality of light emitting parts 4, or may include a plurality of drivers IC provided for each of a plurality of groups in the plurality of light emitting parts 4. Alternatively, the driver IC may include a plurality of sub-drivers IC provided for each or each group of the plurality of light emitting parts 4, and a main driver IC that integrally controls operations of the plurality of sub-drivers IC, and the main driver IC and the sub-drivers IC may cooperate to drive one or more light emitting parts 4. When each group of the plurality of the light emitting parts 4 is driven to light up, the number of the light emitting parts 4 included in each group can be optimized in accordance with the thickness of the wiring 34, the area of one wiring substrate 3, the interval between the plurality of light emitting parts 4 mounted on the wiring substrate 3, and the like.

The number of the light emitting parts 4, which is one or more light emitting parts 4, is not limited to 36, and can be appropriately changed in accordance with the specifications or the like of the image display device 100. The light emitting parts 4 need not be disposed on all of the inner lateral surfaces including the pair of long lateral surfaces 11a and the pair of short lateral surfaces 11b, and may be disposed on at least one of the inner lateral surfaces.

A different number of light emitting parts 4 may be disposed on each inner lateral surface of the pair of long lateral surfaces 11a and the pair of short lateral surfaces 11b. In FIGS. 3A to 7, one or more light emitting parts 4 included in the image display device 100 are partially illustrated to facilitate understanding of the description.

As illustrated in FIG. 7, the light emitting part 4 according to the present embodiment includes a mounting surface 42 facing the wiring portion 33 of the wiring substrate 3 and a light emission surface 43 meeting and connected to the mounting surface 42. The light emitting part 4 also includes a first main surface 41 located on the opposite side to the mounting surface 42, and a second main surface 44 located on the opposite side to the light emission surface 43. The light emission surface 43 is a surface extending along the display surface 21 illustrated in FIG. 1 and meeting the mounting surface 42. For example, the light emission surface 43 is a surface orthogonally meeting the mounting surface 42.

The light emitting part 4 is a lateral-surface light-emitting type, that is, a side view type light emitting part mounted in such a manner that the mounting surface 42 thereof faces the wiring portion 33 of the wiring substrate 3. The light from the light emitting part 4 can be emitted from the light emission surface 43. In other words, the light from the light emitting part 4 can be emitted in a direction in which the display surface 21 of the display unit 2 faces, as illustrated in FIG. 1.

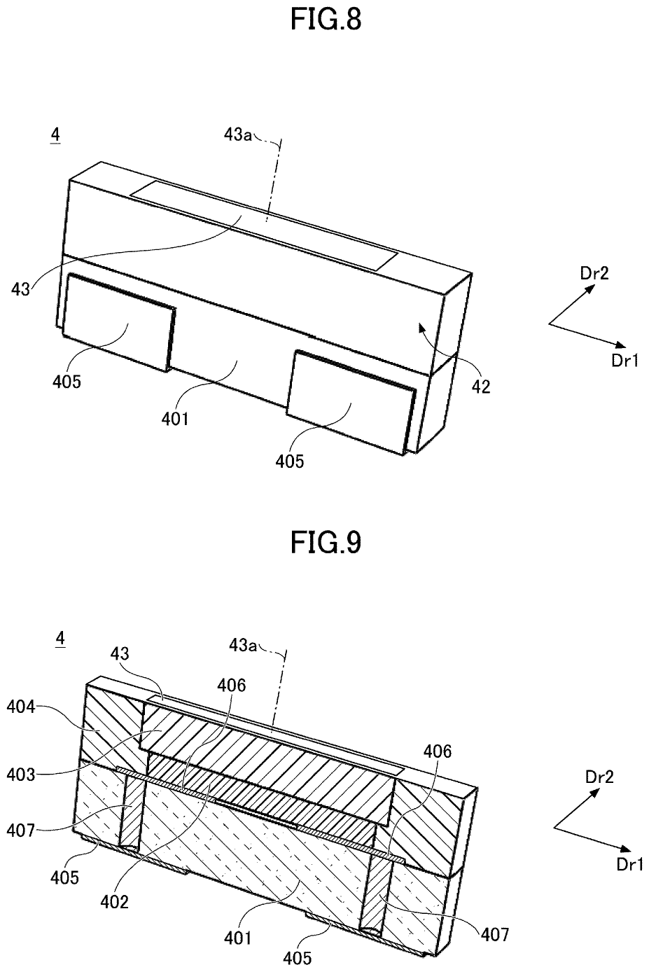

As illustrated in FIGS. 6 and 7, the light emitting part 4 has a rectangular shape elongated in a first direction Dr1 in a plan view. For example, the light emitting part 4 has a rectangular shape elongated in the first direction Dr1 in a plan view of the light emission surface 43. A second direction Dr2 is a direction orthogonal to the first direction Drl on the light emission surface 43. Since the long lateral surface 11a and the short lateral surface 11b of the housing 1 are orthogonal to each other, the first direction Dr1 in the case in which the light emitting part 4 is disposed on the long lateral surface 11a is orthogonal to the first direction Dr1 in the case in which the light emitting part 4 is disposed on the short lateral surface 11b. Similarly, the second direction Dr2 in the case in which the light emitting part 4 is disposed on the long lateral surface 11a is orthogonal to the second direction Dr2 in the case in which the light emitting part 4 is disposed on the short lateral surface 11b. The first direction Dr1 in FIG. 8 is the longitudinal direction of the rectangular shape when the light emitting part 4 is disposed on the long lateral surface 11a. The second direction Dr2 is the direction orthogonal to the first direction Dr1 on the light emission surface 43. When the light emitting part 4 is disposed on the short lateral surface 11b, the second direction Dr2 in FIG. 8 is regarded as the first direction Dr1, and the first direction Dr1 in FIG. 8 is regarded as the second direction Dr2.

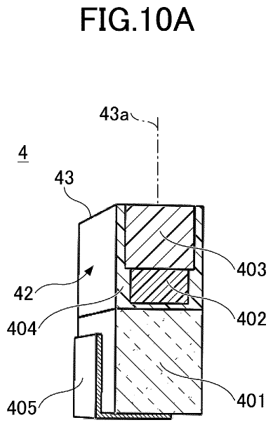

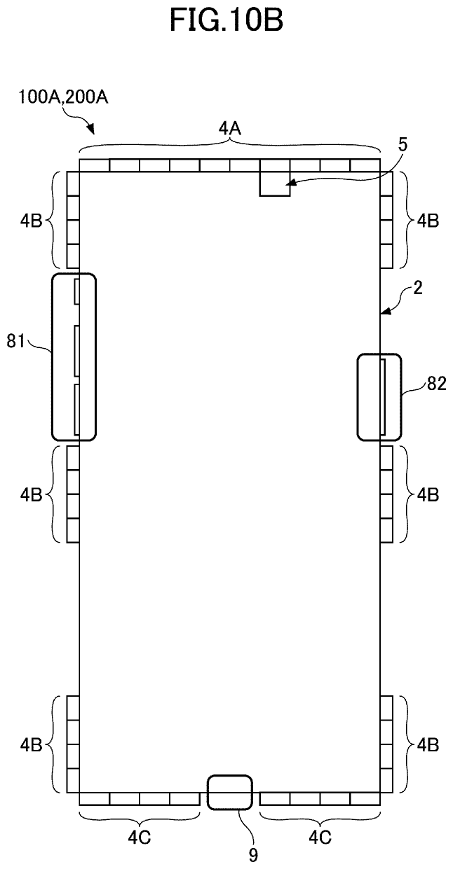

Configuration Example of Light emitting part 4 A configuration of the light emitting part 4 is described in detail with reference to FIGS. 8 to 10A. FIG. 8 is a perspective view of the light emitting part 4. FIG. 9 is a cross-sectional view of the light emitting part 4 including a normal line 43a of the light emission surface 43 of the light emitting part 4, and taken along the mounting surface 42. FIG. 10A is a cross-sectional view of the light emitting part 4 including the normal line 43a of the light emission surface 43 of the light emitting part 4, and intersecting the mounting surface 42 orthogonally.

As illustrated in FIGS. 8 to 10A, the light emitting part 4 includes a substrate 401, a light-emitting element 402, a wavelength conversion layer 403, a light reflective member 404, a first electrode 405, a second electrode 406, and a conductive member 407.

Preferably, the substrate 401 is made of an insulating material as the base material and is made of a material having a certain strength. A material that easily transmits light emitted from the light emitting part 4, external light, or the like is also preferably used.

Specifically, the substrate 401 can be made of ceramics such as alumina, aluminum nitride, mullite, or silicon nitride, phenol resin, epoxy resin, polyimide resin, BT resin, polyphthalamide, polyester resin, or other resins as the base material.

The substrate 401 has a lower surface and an upper surface, and includes at least a pair of positive and negative first electrodes 405 on the lower surface and the lateral surface of the substrate 401, and at least a pair of positive and negative second electrodes 406 on the upper surface. The first electrode 405 and the second electrode 406 are electrically connected to each other by the conductive member 407 disposed inside the substrate 401.

The conductive member 407 is made by disposing a material containing a conductive substance in a through hole inside the substrate 401.

The light-emitting element 402 includes at least a pair of positive and negative element electrodes. The light-emitting element 402 is mounted on the substrate 401, and the second electrode 406 of the substrate 401 is electrically connected to an element electrode of the light-emitting element 402. Preferably, the light-emitting element 402 includes various semiconductors, such as a group III-V compound semiconductor or a group II-VI compound semiconductor. As the semiconductor, preferably, a nitride-based semiconductor such as In_{X}Al_{Y}Ga_{1-X-Y}N (0≤X, 0≤Y, X+Y≤1) or the like is used, and InN, AIN, GaN, InGaN, AlGaN, InGaAIN, and the like can also be used. For example, the light-emitting element 402 is an LED or a laser diode (LD). Preferably, a light emission peak wavelength of the light-emitting element 402 is in a range from 400 nm to 530 nm, more preferably in a range from 420 nm to 490 nm, and even more preferably in a range from 440 nm to 475 nm, from the viewpoints of light emission efficiency, excitation of a phosphor which will be described later, and the like.

The wavelength conversion layer 403 is disposed on the light-emitting element 402. The wavelength conversion layer 403 is a member having, for example, a substantially rectangular outer shape in a plan view. The wavelength conversion layer 403 is provided so as to cover the upper surface of the light-emitting element 402. The wavelength conversion layer 403 can be made using a light-transmissive resin material, or an inorganic material such as ceramic or glass. As the resin material, a thermosetting resin, such as a silicone resin, a silicone modified resin, an epoxy resin, an epoxy modified resin, or a phenol resin, can be used. As the wavelength conversion layer 403, a thermoplastic resin, such as a polycarbonate resin, an acrylic resin, a methyl pentene resin, or a polynorbornene resin, can be used. Particularly, a silicone resin or a modified resin thereof with good light resistance and heat resistance is preferably used. Preferably, the “light-transmissive” as used herein preferably refers to transmitting 60% or more of the light from the light-emitting element 402. The wavelength conversion layer 403 includes, in addition to the above-described resin, phosphor that converts the wavelength of at least part of light from the light-emitting element 402. For example, the wavelength conversion layer 403 may be made of a resin material, ceramic, or glass containing phosphor, or a sintered body of phosphor. The wavelength conversion layer 403 may also be multi-layered in which a resin layer containing phosphor is disposed on a molded body made of resin, ceramic, glass, or the like.

As the phosphor contained in the wavelength conversion layer 403, an yttrium aluminum garnet-based phosphor (for example, (Y,Gd)₃(Al,Ga)₅O₁₂:Ce), a lutetium aluminum garnet-based phosphor (for example, Lu₃(Al,Ga)₅O₁₂:Ce), a terbium aluminum garnet-based phosphor (for example, Tb₃(Al,Ga)₅O₁₂:Ce), a CCA-based phosphor (for example, Ca₁₀(PO₄)₆Cl₂:Eu), an SAE-based phosphor (for example, Sr₄Al₁₄O₂₅:Eu), a chlorosilicate-based phosphor (for example, Ca₈MgSi₄O₁₆Cl₂:Eu), a silicate-based phosphor (for example, (Ba,Sr,Ca,Mg)₂SiO₄:Eu), an oxynitride-based phosphor such as a β-SiAlON-based phosphor (for example, (Si,Al)₃(O,N)₄:Eu) or an α-SiAION-based phosphor (for example, Ca(Si,Al)₁₂(O,N)₁₆:Eu), a nitride-based phosphor such as an LSN-based phosphor (for example, (La,Y)₃Si₆N₁₁:Ce), a BSESN-based phosphor (for example, (Ba,Sr)₂Si₅N₈:Eu), an SLA-based phosphor (for example, SrLiAl₃N₄:Eu), a CASN-based phosphor (for example, CaAlSiN₃:Eu), or an SCASN-based phosphor (for example, (Sr,Ca)AlSiN₃:Eu), a fluoride-based phosphor such as a KSF-based phosphor (for example, K₂SiF₆:Mn), a KSAF-based phosphor (for example, K₂(Si₁₋ₓAlₓ)F₆₋ₓ:Mn, where x satisfies 0<x<1), or an MGF-based phosphor (for example, 3.5MgO·0.5MgF₂·GeO₂:Mn), a quantum dot having a perovskite structure (for example, (Cs,FA,MA)(Pb,Sn)(F,Cl,Br,I)₃, where FA and MA represent formamidinium and methylammonium, respectively), a group II-VI quantum dot (for example, CdSe), a group III-V quantum dot (for example, InP), a quantum dot having a chalcopyrite structure (for example, (Ag,Cu)(In,Ga)(S,Se)₂), or the like can be used. The phosphors described above are particles. One of these types of phosphors can be used alone, or two or more of these types of phosphors can be used in combination.

In the embodiment, the light emitting part 4 uses a blue light-emitting element as the light-emitting element 402, and the wavelength conversion layer 403 contains the phosphor that converts the wavelength of light emitted from the light-emitting element 402 to green and red, so that a white light is emitted. The wavelength conversion layer 403 may contain a light scattering substance, and titanium oxide, barium titanate, aluminum oxide, silicon oxide, or the like can be used as the light scattering substance.

The light reflective member 404 covers the lateral surface of the light-emitting element 402. With this configuration, the light leaking from the lateral surface of the light-emitting element 402 is reduced, improving the extraction efficiency of light emitted from the light-emitting element 402. The upper surface of the wavelength conversion layer 403 is exposed from the light reflective member 404 and serves as the light emission surface 43 of the light emitting part 4. The light reflective member 404 is preferably made of a member having a high light reflectivity to improve the light extraction efficiency. For example, as the light reflective member 404, a resin material containing a light scattering substance such as white pigment can be used.

Examples of the light scattering substance include titanium oxide, zinc oxide, magnesium oxide, magnesium carbonate, magnesium hydroxide, calcium carbonate, calcium hydroxide, calcium silicate, magnesium silicate, barium titanate, barium sulfate, aluminum hydroxide, aluminum oxide, zirconium oxide, and silicon oxide. Preferably, one of these types is used alone, or a combination of two or more of these types are used. The resin material is preferably a material in which a resin material including a thermosetting resin, such as an epoxy resin, an epoxy modified resin, a silicone resin, a silicone modified resin, a phenol resin, or the like, as a main component is used as a base material.

As the light emitting part 4, a lateral-surface light-emitting type (side view type) light-emitting device disclosed in Japanese Patent Publication No. 2019-16766 A can be used. The content of the light-emitting device disclosed in Japanese Patent Publication No. 2019-16766 A is incorporated herein by reference.

### Effects of Image Display Device 100 and Smartphone 200

In smartphones, it may not be possible to place the light emitting part for illumination, due to space constraints, on the side of a smartphone on which the imaging device for selfies is located. Smartphones that do not have the light emitting part for illumination may not produce high-quality images because illumination cannot be used and the area around the operator is dark during videophone calls, moving image shooting, personal authentication, or other applications.

In smartphones that do not have the light emitting part for illumination on the side of the smartphone on which the imaging device for selfies is located, a screen light may be used as a flash for illumination when capturing still images with the imaging device for selfies.

The screen light is a white light emitted from the entire display surface of the display unit by displaying a pure white image on the display surface for several seconds. The display surface in this case functions as a surface light source that illuminates the operator who takes a selfie. In a case in which the display surface is caused to function as the screen light, the display surface becomes a pure white image, and thus the operator cannot visually recognize the image being shot during shooting. Therefore, in smartphones, the screen light cannot be used for moving image shooting by the imaging device for selfies, and a high-quality moving image may not be obtained in dark environments around the smartphone or the operator. In addition, at the time of shooting of the moving image, in an environment in which the operator cannot visually recognize the image being shot during the shooting, there is a possibility that the shooting of the moving image is difficult.

In the present embodiment, as illustrated in FIG. 1, the image display device 100 includes the inner lateral surfaces 11, the housing 1 having the opening portion 12 defined by the inner lateral surfaces 11, and the display unit 2 disposed in the opening portion 12 on an inner side relative to the inner lateral surfaces 11 of the housing 1 and having the display surface 21 and the lateral surface 22 connected to the display surface 21. The image display device 100 also includes the wiring substrates 3, each disposed on a corresponding one of the inner lateral surfaces 11 of the housing 1 and each including the wiring portions 33 at least on a side opposite to a surface thereof facing the inner lateral surface 11, and the one or more light emitting parts 4, each disposed between a corresponding one of the inner lateral surfaces 11 of the housing 1 and a corresponding one of the lateral surfaces 22 of the display unit 2 and disposed on corresponding ones of the wiring portions 33. The light emitting part 4 includes the mounting surface 42 facing the wiring portions 33 of the wiring substrate 3, and the light emission surface 43 meeting and connected to the mounting surface 42. Light from the light emitting part 4 can be emitted in a direction in which the display surface 21 faces.

With the image display device 100 including the light emitting part 4 including the mounting surface 42 along the inner lateral surface 11 of the housing 1 and the light emission surface 43 along the display surface 21, light can be emitted in the direction in which the display surface 21 faces from the light emitting part 4 disposed in the narrow space between the inner lateral surfaces 11 of the housing 1 and the lateral surfaces 22 of the display unit 2. Therefore, the image display device 100 uses the light emitted from the light emitting part 4 in the direction in which the display surface 21 faces as illumination in capturing images including still images and moving images by the imaging device 5 for selfies to obtain high-quality images even when it is dark around the smartphone or the operator. The image display device 100 can also display an image being captured on the display surface 21 for the operator during shooting of motion to allow the operator to visually recognize the image.

Accordingly, the operator easily shoots a moving image. The image display device 100 may produce higher-quality still images with auxiliary light from the light emitting part even when the surrounding area is dark, and can also use the light emitted from the light emitting part 4 in the direction in which the display surface 21 faces as a flash in taking still images with the imaging device 5 for selfies.

Further, the image display device 100 does not require the recessed portion in the light guide member for housing the light emitting part, as is provided in the smartphone disclosed in Patent Document 1, and thus does not require an assembly process with a high degree of technical difficulty to accurately house the light emitting part in the recessed portion of the light guide member. That is, the process of aligning the light emitting part 4 with the light guide member, and the process of attaching the light guide member to the housing 1 can be omitted. This reduces the assembly labor. As a result, the present embodiment facilitates the assembly of the image display device 100, which includes the light emitting parts 4 disposed on the inner lateral surfaces 11 of the housing 1 and can emit light in the direction in which the display surface 21 of the display unit 2 faces, thus increasing the productivity of the image display device 100.

In an example of the image display device, when the light emitting part 4 is electrically connected to the drive control substrate by conductors or the like, and the light emitting part breaks down or the like, it may be necessary to replace the drive control substrate with a new one or to perform wiring work and the like to repair the light emitting part, causing a difficulty in handling the failure. In the present embodiment, the light emitting part 4 is mounted via the wiring substrate 3, so that the light emitting part 4, or the wiring substrate 3 on which the light emitting part 4 is mounted, can be easily removed from the image display device 100 even in the case of breaking down or the like of the light emitting part 4. This facilitates handling of the failures such as replacement, repair, or the like of the wiring substrate 3 and the light emitting part 4.

Furthermore, since the wiring substrate 3 in the image display device 100 has flexibility, the wiring substrate 3 can be easily disposed even in the narrow space or the space including a bent portion in the image display device 100. This reduces restrictions on the placement of the wiring substrate 3.

The light emitting part 4 in the image display device 100 includes the light-emitting element 402 and the wavelength conversion layer 403 disposed on the light-emitting element 402. This allows the image display device 100 to emit mixed-color light of the light from the light-emitting element 402 and the light subjected to wavelength conversion by the wavelength conversion layer 403. This allows for the use of the mixed-color light such as the white light as illumination for shooting.

Each of the plurality of the light emitting parts 4 in the image display device 100 includes one light-emitting element 402, and the light-emitting element 402 (in other words, the light emitting part 4) is controllable to be turned on individually or for each group. This enables the image display device 100 to partially irradiate only a partial region of the irradiation surface with light emitted by the plurality of light emitting parts 4 (hereinafter referred to as partial irradiation).

One light emitting part 4 may include at least two light-emitting elements 402, and two or more light-emitting elements 402 may be controllable to be turned on individually or for each group. With this configuration, the effect of allowing for partial irradiation can also be achieved. Since such an image display device 100 can perform partial irradiation with a small number of light emitting parts 4, the area in which the light emitting parts 4 are located can be reduced, and the space saving can be achieved.

When shooting with the imaging device 5 for selfies, the operator performs the shooting operations while watching the display surface 21 of the display unit 2, so that preferably the light from the light emitting part 4 located near the display surface 21 is not dizzy to the operator. To obtain high-quality captured images, the light from the light emitting part 4 is preferably bright light. For example, when the light emitted from a single light emitting part has a significant unevenness in illuminance, and when the overall brightness of the irradiation light is reduced to avoid glare, the brightness may be insufficient in areas with low-illuminance irradiation light, and high-quality captured images may not be obtained. When the light emitted from one light emitting part is made brighter overall to obtain a bright captured image, the light may become too bright in areas with high-illuminance irradiation light, and the operator may feel glare. When the image display device 100 includes the plurality of light emitting parts 4 as illustrated in FIG. 1, for example, the irradiation light of the plurality of light emitting parts 4 can be partially superimposed on one another. Thus, while restricting the brightness of the irradiation light of the individual light emitting parts 4, the image display device 100 reduces unevenness in illuminance of the irradiation light among the plurality of light emitting parts 4, and can emit light that ensures necessary illumination for shooting. Accordingly, the image display device 100 can emit bright light with reduced glare for the operator as illumination for shooting by the imaging device 5 for selfies.

In the present embodiment, the area of the light-emitting surface of the light-emitting element 402, that is, the area of the light emission surface 43, may be in a range from 0.02 mm² to 0.22 mm² in a plan view, and the electric current supplied to the light-emitting element 402 may be in a range from 0.05 mA to 5 mA. The range of the area and the range of the driving current of the light-emitting surface of the light-emitting element 402 are set as described above, so that the image display device 100 that is safe and prevents damage to the light-emitting element 402, while using a small-sized light-emitting element 402, in other words, a low-cost light-emitting element 402, can be provided.

In the present embodiment, the size of the light-emitting surface of the light-emitting element 402, that is, the size of the light emission surface 43 may be in a range from 0.1 mm² to 2 mm² in a plan view, and the electric current supplied to the light-emitting element 402 may be in a range from 0.5 mA to 100 mA. The range of the area and the range of the driving current of the light-emitting surface of the light-emitting element 402 are set as described above, so that the image display device 100 that is safe and prevents damage to the light-emitting element 402, while using a small-sized light-emitting element 402, in other words, a low-cost light-emitting element 402, can be provided.

The smartphone 200 including the image display device 100 can also obtain the above-described effects of the image display device 100.

### Modified Examples

FIG. 10B is a schematic plan view illustrating an example of an image display device 100A according to a variation of the first embodiment. As illustrated in FIG. 10B, an image display device 100A according to the variation is included in a smartphone 200A, and is different from the above-described embodiment mainly in that a light emitting part group 4A, light emitting part groups 4B, light emitting part groups 4C, three left side buttons 81, one right side button 82, and a connection interface 9 are provided.

The three left side buttons 81 and the right side button 82 of the smartphone 200A are operation buttons used for turning on/off the power supply or operation of the smartphone 200A, and are disposed at positions surrounded by rectangular frames in FIG. 10B. The connection interface 9 disposed at a position surrounded by a rectangular frame in FIG. 10B is a connection interface for connecting a charging cable or the like.

In the image display device 100A according to the variation, six light emitting part groups 4B and two light emitting part groups 4C are arranged so as to avoid the positions where the three left side buttons 81, the right side button 82, and the connection interface 9 of the smartphone 200A are arranged. In the image display device 100A, the arrangement is not limited to that illustrated in FIG. 10B, and each of the light emitting part group 4A, the light emitting part groups 4B, and the light emitting part groups 4C can be appropriately arranged in accordance with and avoiding the arrangement of the side buttons, the connection interface, and the like included in the smartphone 200A.

The light emitting part group 4A includes ten light emitting parts 4. The light emitting part group 4A is arranged on one of the two short sides of the display unit 2 of the image display device 100A, so that the ten light emitting parts 4 are aligned on the outside of the display unit 2 along the short side in a plan view. The ten light emitting parts 4 of the light emitting part group 4A are individually controllable to be turned on. Since the light emitting part group 4A in the vicinity of the imaging device 5 can light up individually, the direction and density of the shadow created behind the operator can be adjusted, making it possible to take dramatic photos and moving images according to a desired purpose.

The light emitting part groups 4B include six groups, each of which includes four light emitting parts 4. Three groups of the light emitting part groups 4B are arranged on one of the two long sides of the display unit 2 of the image display device 100A, so that the four light emitting parts 4 are aligned on the outside of the display unit 2 along the long side, and the three groups are spaced apart from each other in a plan view. The other three groups of the light emitting part groups 4B are arranged on the other of the two long sides of the display unit 2 of the image display device 100A, so that the four light emitting parts 4 are aligned on the outside of the display unit 2 along the long side, and the three groups are spaced apart from each other in a plan view. In the light emitting part groups 4B, one light emitting part group 4B including four light emitting parts 4 is collectively controllable to be turned on, thus allowing for the individual lighting control for each of the six groups.

The light emitting part groups 4C include two groups, each of which includes four light emitting parts 4. The two groups of the light emitting part groups 4C are arranged in a plan view on the other of the two short sides of the display unit 2 of the image display device 100A, so that the four light emitting parts 4 are aligned on the outside of the display unit 2 along the short side, and the two groups are spaced apart from each other. In the light emitting part groups 4C, one light emitting part group 4C including four light emitting parts 4 is collectively controllable to be turned on, thus allowing for the individual lighting control for each of the two groups.

In the image display device 100A illustrated in FIG. 10B, to facilitate understanding of the arrangement relationship, the outer shapes of the display unit 2 and the imaging device 5 in a plan view are represented by rectangles, but the outer shapes thereof in a plan view are not limited to the rectangles.

### SECOND EMBODIMENT

Next, an image display device according to a second embodiment is described. The same names and reference characters as those in the previously described embodiment indicate the same members or configurations, or members or configurations of the same quality, and the detailed description thereof will be omitted as appropriate. This also applies to other embodiments which will be described below.

The image display device according to the present embodiment is different from the first embodiment mainly in that each of one or more light emitting parts includes at least one lens disposed to face the light emission surface 43.

### Configuration Example of Image Display Device 100a

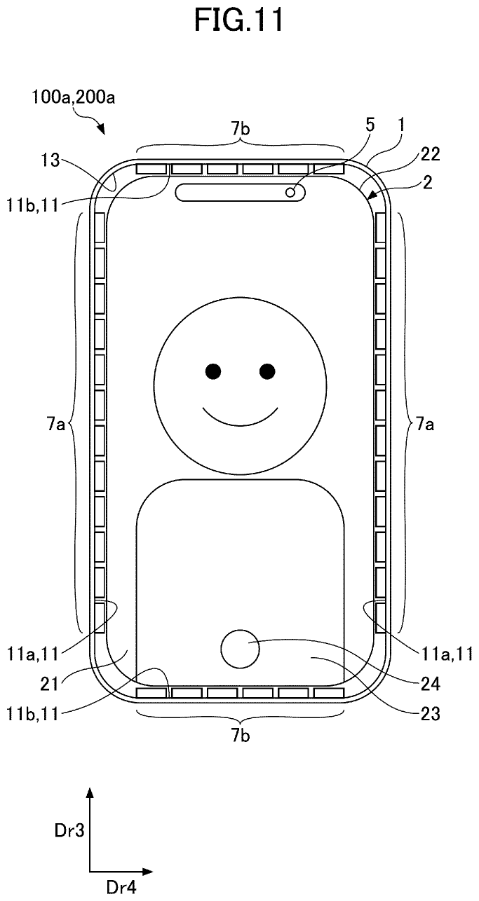

FIG. 11 is a schematic plan view of an image display device 100a according to a second embodiment. As illustrated in FIG. 11, the image display device 100a according to the present embodiment is different from the image display device 100 according to the first embodiment in that at least one first light source structure 7a and at least one second light source structure 7b are included. The image display device 100a is included in a smartphone 200a.

In the present embodiment, the at least one first light source structure 7a and the at least one second light source structure 7b are disposed between the inner lateral surfaces 11 of the housing 1 and the lateral surfaces 22 of the display unit 2. The first light source structure 7a is disposed along a long lateral surface 11a. The second light source structure 7b is disposed along a short lateral surface 11b. In the example illustrated in FIGS. 11, 24 first light source structures 7a are disposed on a pair of long lateral surfaces 11a of the housing 1, in other words, 12 first light source structures 7a are disposed on one long lateral surface 11a. 12 second light source structures 7b are disposed on a pair of short lateral surfaces 11b of the housing 1, in other words, six second light source structures 7b are disposed on one short lateral surface 11b.

However, the number of the first light source structures 7a is not limited to 24, and can be appropriately changed in accordance with the specifications and the like of the image display device 100a. The first light source structure 7a may be disposed on at least one long lateral surface 11a of the pair of long lateral surfaces 11a. Different numbers of the first light source structures 7a may be disposed on the pair of long lateral surfaces 11a.

Similarly, the number of the second light source structures 7b is not limited to 12 and can be appropriately changed in accordance with the specifications and the like of the image display device 100a. The second light source structures 7b may be disposed on at least one short lateral surface 11b of the pair of short lateral surfaces 11b. Different numbers of the second light source structures 7b may be disposed on the pair of short lateral surfaces 11b.

In the present embodiment, the inner lateral surfaces 11 of the housing 1 include a curved surface 13 between the long lateral surface 11a and the short lateral surface 11b in a plan view. In the present embodiment, the first light source structure 7a and the second light source structure 7b are not disposed on the curved surface 13.

### Configuration Example of First Light Source Structure 7a

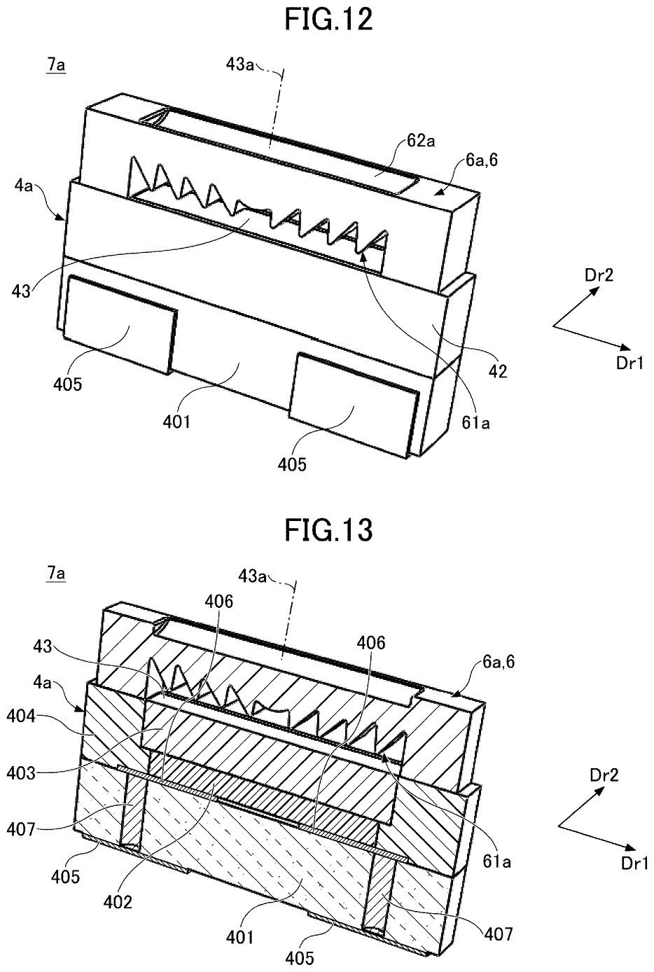

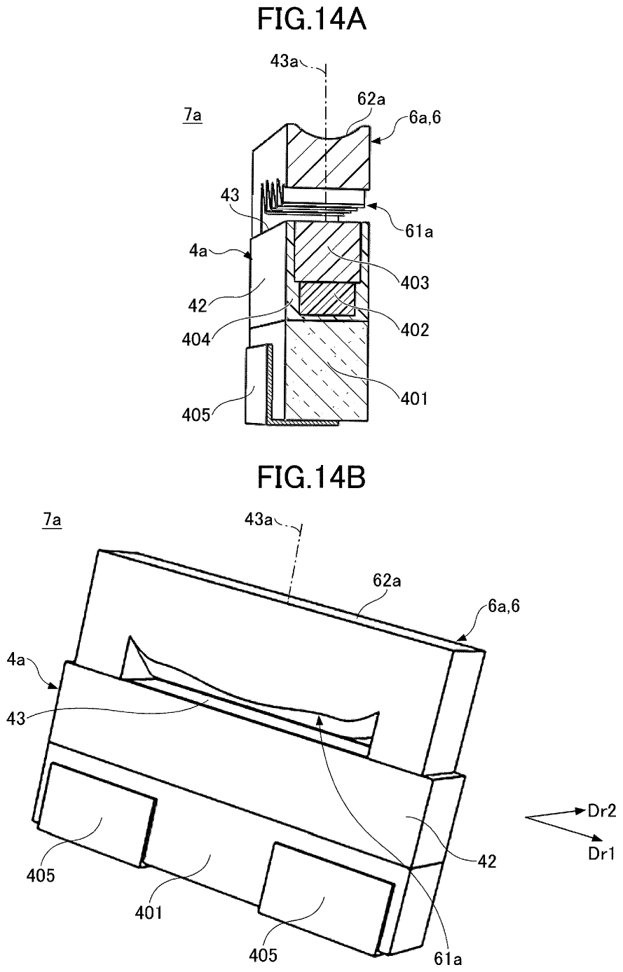

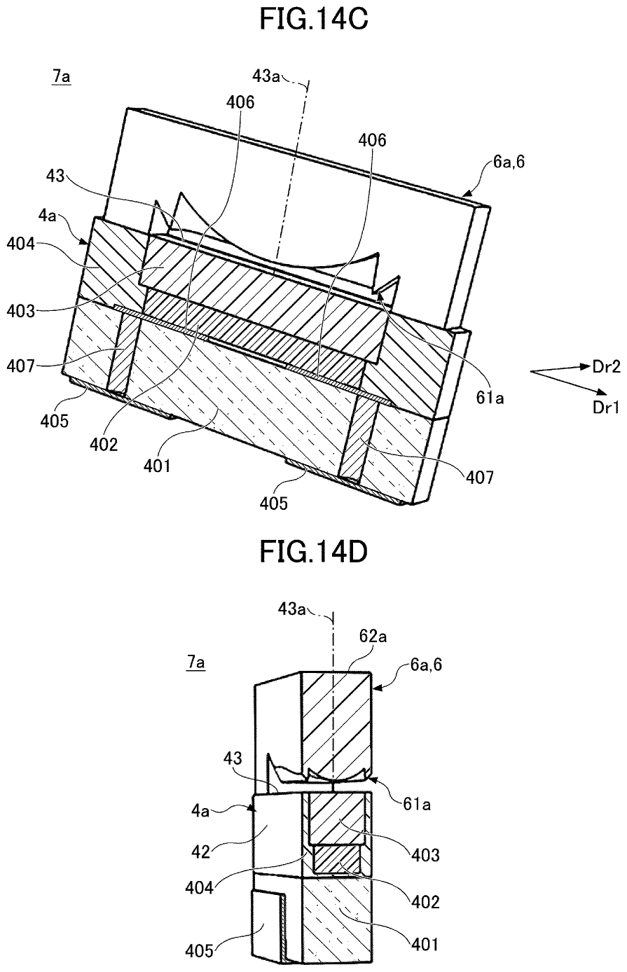

Next, the configuration of the first light source structure 7a is described with reference to FIGS. 12 to 14A. FIG. 12 is a perspective view of a first example of the first light source structure 7a. FIG. 13 is a cross-sectional view of the first example of the first light source structure 7 a including the normal line 43a of the light emission surface 43 of the first light source structure 7a, and taken along the mounting surface 42. FIG. 14A is a cross-sectional view of the first example of the first light source structure 7a including the normal line 43a of the light emission surface 43 of the first light source structure 7a, and intersecting the mounting surface 42 orthogonally.

As illustrated in FIGS. 12 to 14A, the first light source structure 7a according to the present embodiment includes a first light emitting part 4a and a first lens 6a. The first light emitting part 4a may be identical to the light emitting part 4 according to the first embodiment. The first lens 6a is disposed on the same surface side as and facing the light-emitting surface 43 of the light reflective member 404 of the first light emitting part 4a. The first lens 6a is bonded to the light reflective member 404 of the first light emitting part 4a with an adhesive, an adhesive tape, or the like. The first lens 6a and the light reflective member 404 of the first light emitting part 4a may be bonded by molding. The first lens 6a is an example of at least one lens 6 disposed to face the light emission surface 43 of light emitting part 4. In the following description, at least one lens 6 disposed to face the light emission surface 43 of the light emitting part 4 may be collectively referred to as the light source structure 7.

In the present embodiment, the first lens 6a includes a first surface 61a facing the light emission surface 43 and a second surface 62a located on the opposite side to the first surface 61a. The first lens 6a is made of resin, glass, or the like having transmissivity.

Preferably, the transmissivity herein refers to transmitting 60% or more of the light from the first light emitting part 4a.

In the present embodiment, the first surface 61a is a lens surface having a curvature only in the first direction Dr1. The second surface 62a may be a flat surface, but is preferably a lens surface having a curvature only in the second direction Dr2. The first surface 61a is a Fresnel lens surface. The second surface 62a is a cylindrical lens surface.

In the present embodiment, the first lens 6a has a rectangular shape with long sides and short sides in a plan view, and includes a third surface facing the light emission surface 43 and a fourth surface located on the opposite side to the third surface. The first surface 61a provided as the Fresnel lens surface having a curvature only in the long-side direction corresponds to the third surface. The second surface 62a provided as the cylindrical lens surface having a curvature only in the short-side direction corresponds to the fourth surface. The second surface 62a is one concave surface in a cross section including the normal line 43a of the light emission surface 43 and intersecting the mounting surface 42 orthogonally.

The first light source structure 7a is disposed such that the long sides of the first lens 6a extend along a third direction Dr3 illustrated in FIG. 11. For example, the first light source structure 7a is disposed on the long lateral surface 11a in FIG. 11.

In the present embodiment, the Fresnel lens surface provided on the first surface 61a is a surface including convex portions in a rectangular region in which the optical axis of the lens 6, that is, the normal line 43a of the light emission surface 43 substantially coincides with the center of the Fresnel lens among a plurality of convex portions which divide the lens into concentric regions in a plan view. Accordingly, the first surface 61a has the Fresnel lens function in a small area, and can thus decrease the size of the first light source structure 7a.

However, the first surface 61a may be a lens surface having a curvature only in the second direction Dr2. The second surface 62a may be a lens surface having a curvature only in the first direction Dr1. The first surface 61a may be the cylindrical lens surface.

The second surface 62a may be the Fresnel lens surface. The second surface 62a may be the Fresnel lens surface having a curvature only in the long-side direction. The first surface 61a may be the cylindrical lens surface having a curvature only in the short-side direction. The first lens 6a may include at least one of the Fresnel lens surface or the lens surface including a total reflection portion. For example, the lens surface including the total reflection portion is a total internal reflection (TIR) lens surface. Herein, FIGS. 14B to 14D illustrate a second example of the first lens 6a. The first lens 6a according to the second example includes the TIR lens. The Fresnel lens surface is not limited to a surface corresponding to the convex surface, and may be a surface corresponding to the concave surface. The cylindrical lens surface is not limited to the concave surface, and may be the convex surface.

### Configuration Example of Second Light Source Structure 7b

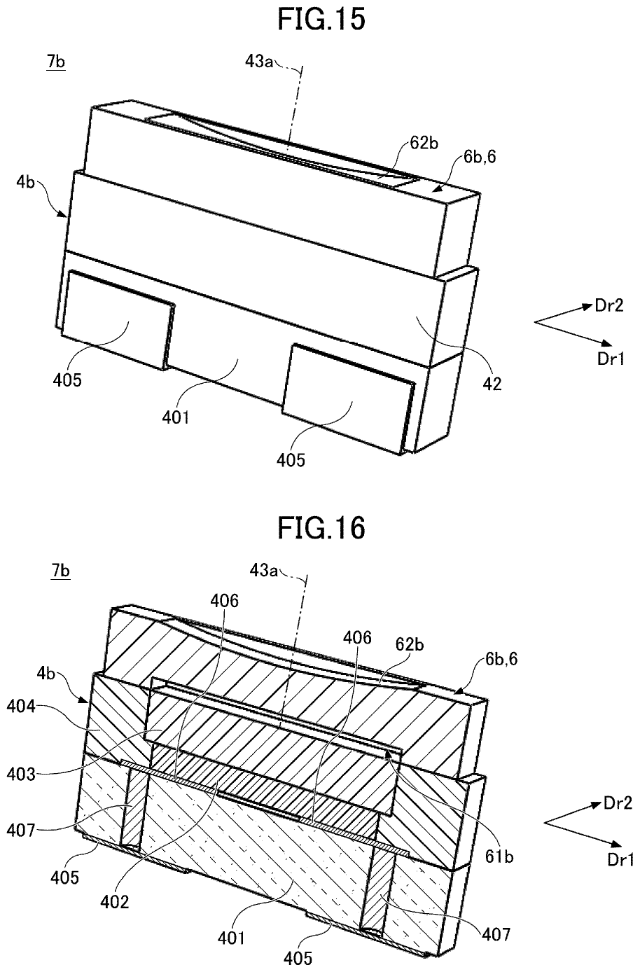

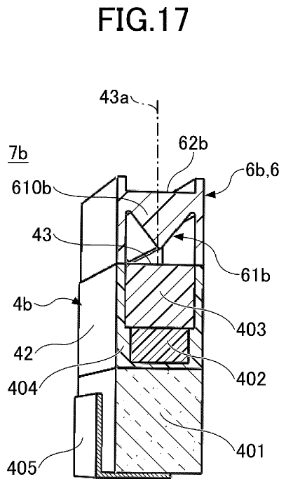

A configuration of the second light source structure 7b is described with reference to FIGS. 15 to 17. FIG. 15 is a perspective view of the second light source structure 7b. FIG. 16 is a cross-sectional view of the second light source structure 7 b including the normal line 43a of the light emission surface 43 of the second light source structure 7b, and taken along the mounting surface 42. FIG. 17 is a cross-sectional view of the second light source structure 7b including the normal line 43a of the light emission surface 43 of the second light source structure 7b, and intersecting the mounting surface 42 orthogonally.

As illustrated in FIGS. 15 to 17, the second light source structure 7b according to the present embodiment includes a second light emitting part 4b and a second lens 6b. The second light emitting part 4b may be identical to the light emitting part 4 according to the first embodiment. The second lens 6b is disposed to face the light emission surface 43 of the second light emitting part 4b. The second lens 6b is an example of at least one lens 6 disposed to face the light emission surface 43 of the light emitting part 4.

In the present embodiment, the second lens 6b includes a first surface 61b facing the light emission surface 43, and a second surface 62b located on the opposite side to the first surface 61b. The second lens 6b is made of resin, glass, or the like having transmissivity. Preferably, the transmissivity herein refers to transmitting 60% or more of the light from the second light emitting part 4b.

In the present embodiment, the first surface 61b is a lens surface having a curvature only in the second direction Dr2. The second surface 62b may be a flat surface, but is preferably a lens surface having a curvature only in the first direction Dr1. The first surface 61b is a Fresnel lens surface. The second surface 62b is a cylindrical lens surface.

In the present embodiment, the second lens 6b has a rectangular shape with long sides and short sides in a plan view, and includes a fifth surface facing the light emission surface 43 and a sixth surface located on the opposite side to the fifth surface. The second surface 62b that is the cylindrical lens surface having a curvature only in the long-side direction corresponds to the sixth surface. The second surface 62b is one concave surface in a cross section including the normal line 43a of the light emission surface 43, and taken along the mounting surface 42. The first surface 61b that is the Fresnel lens surface having a curvature only in the short-side direction corresponds to the fifth surface. The second light source structure 7b is disposed such that the long sides of the second lens 6b extend along the fourth direction Dr4 illustrated in FIG. 11. For example, the second light source structure 7b is disposed on the short lateral surface 11b in FIG. 11.

In the present embodiment, the Fresnel lens surface provided on the first surface 61b is a surface including any one convex portion in a rectangular region among a plurality of convex portions which divide the lens into concentric regions in a plan view. Accordingly, the first surface 61b has the Fresnel lens function in a small area, and can thus decrease the size of the second light source structure 7b. The Fresnel lens surface provided on the first surface 61b may have two or more convex portions.

However, the first surface 61b may be a lens surface having a curvature only in the first direction Dr1. The second surface 62b may be a lens surface having a curvature only in the second direction Dr2. The first surface 61b may be the cylindrical lens surface. The second surface 62b may be the Fresnel lens surface. The second surface 62b may be the Fresnel lens surface having a curvature only in the long-side direction. The first surface 61b may be the cylindrical lens surface having a curvature only in the short-side direction. The second lens 6b may include at least one of the Fresnel lens surface and the lens surface including the total reflection portion. For example, the lens surface including the total reflection portion is a total internal reflection (TIR) lens surface. The Fresnel lens surface is not limited to a surface corresponding to the convex surface, and may be a surface corresponding to the concave surface. The cylindrical lens surface is not limited to the concave surface, and may be the convex surface.

In the present embodiment, in the first lens 6a and the second lens 6b, the first surface 61a and the first surface 61b are Fresnel lens surfaces, and the second surface 62a and the second surface 62b are cylindrical lens surfaces. However, the same or similar effects can be achieved even when the first surface 61a and the first surface 61b are cylindrical lens surfaces, and the second surface 62a and the second surface 62b are Fresnel lens surfaces.

As in the present embodiment, the first surface 61a and the first surface 61b are the Fresnel lens surfaces, so that the convex portions protrude toward the light emission surface 43, which prevents damage to the Fresnel lens surfaces during assembly of the image display device 100a.

### Example of Light Distribution Characteristics of Image Display Device 100a

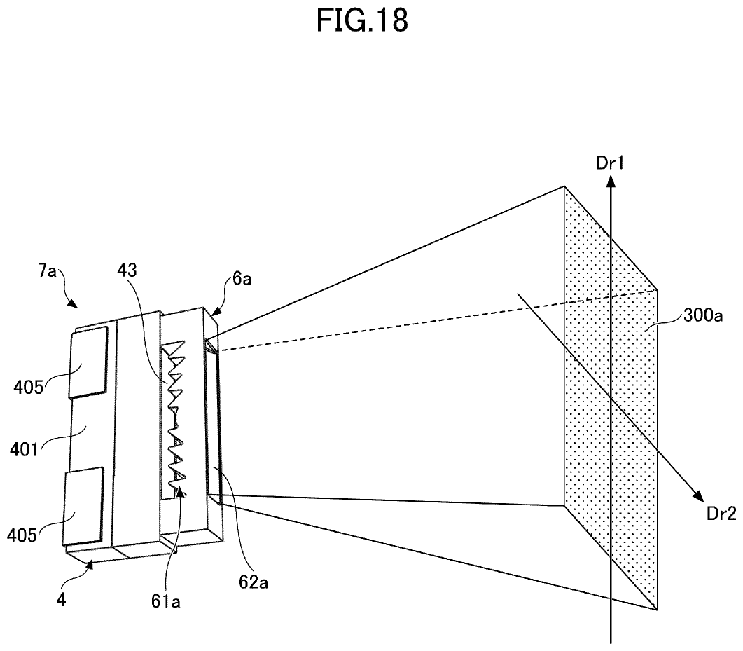

Next, light distribution characteristics of the image display device 100a are described with reference to FIGS. 18 to 22.

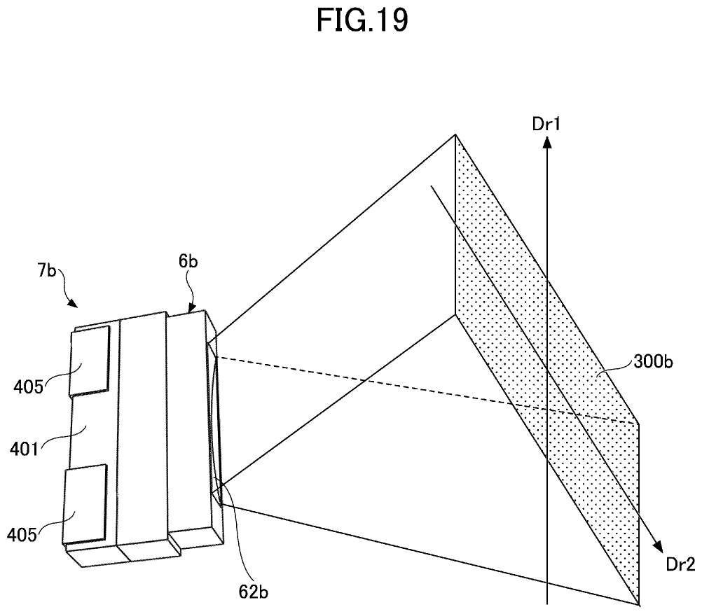

FIG. 18 schematically illustrates light distribution characteristics of the first light source structure 7a. FIG. 19 schematically illustrates light distribution characteristics of the second light source structure 7b. As illustrated in FIG. 18, first irradiation light 300a is emitted from the first light source structure 7a. As illustrated in FIG. 19, second irradiation light 300b is emitted from the second light source structure 7b. The first irradiation light 300a has a rectangular shape with the first direction Dr1 extending in the longitudinal direction thereof in a plan view by the first lens 6a controlling the light distribution in the long-side direction on the first surface 61a, and controlling the light distribution in the short-side direction on the second surface 62a. The second irradiation light 300b has the rectangular shape with the second direction Dr2 extending in the longitudinal direction thereof in a plan view by the second lens 6b controlling the light distribution in the long-side direction on the first surface 61b, and controlling the light distribution in the short-side direction on the second surface 62b. In the present embodiment, the first light source structure 7a and the second light source structure 7b have light distribution characteristics different from each other.

As illustrated in FIG. 11, the first light source structures 7a are disposed on the long lateral surfaces 11a, and the second light source structures 7b are disposed on the short lateral surfaces 11b. The third direction Dr3 of the long lateral surfaces 11a is orthogonal to the fourth direction Dr4 of the short lateral surfaces 11b. Therefore, the longitudinal direction of the first irradiation light 300a from the first light source structure 7a disposed on the inner lateral surface of the housing 1, and the longitudinal direction of the second irradiation light 300b from the second light source structure 7b disposed on the inner lateral surface of the housing 1 are substantially parallel to each other.

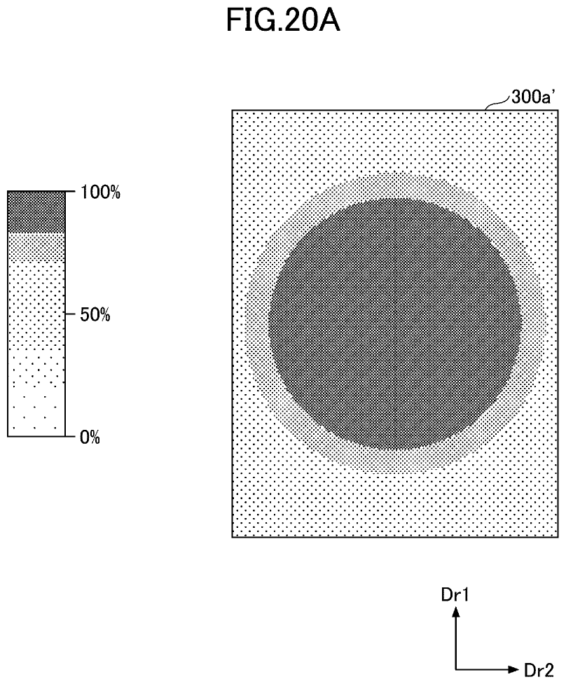

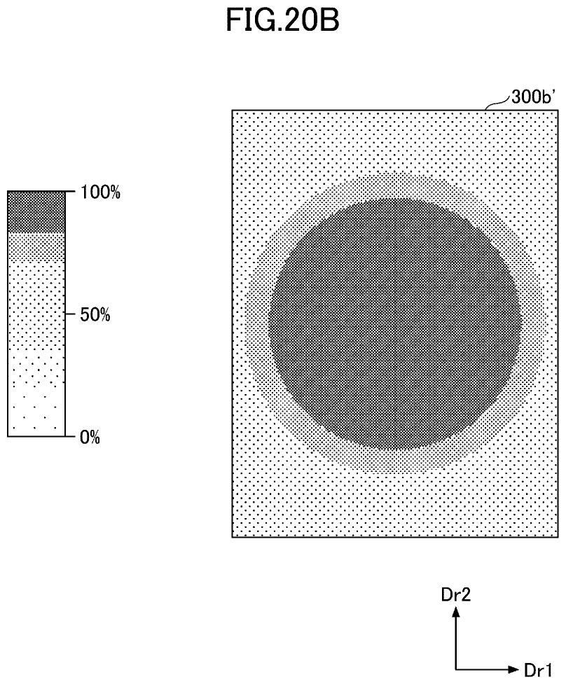

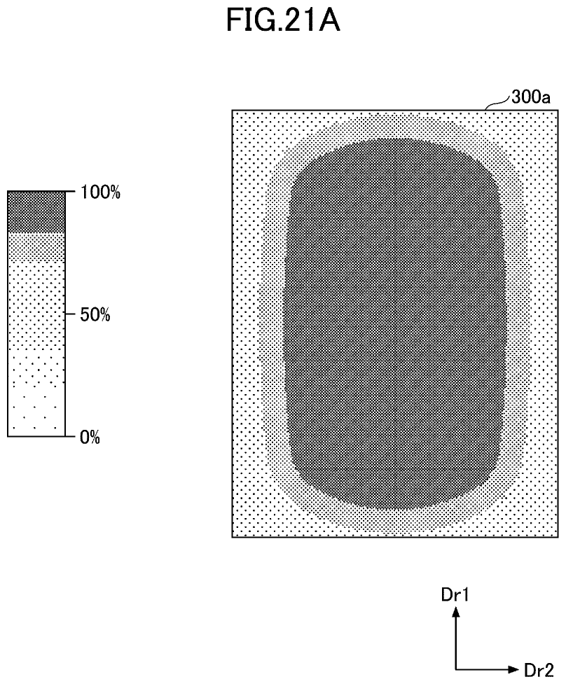

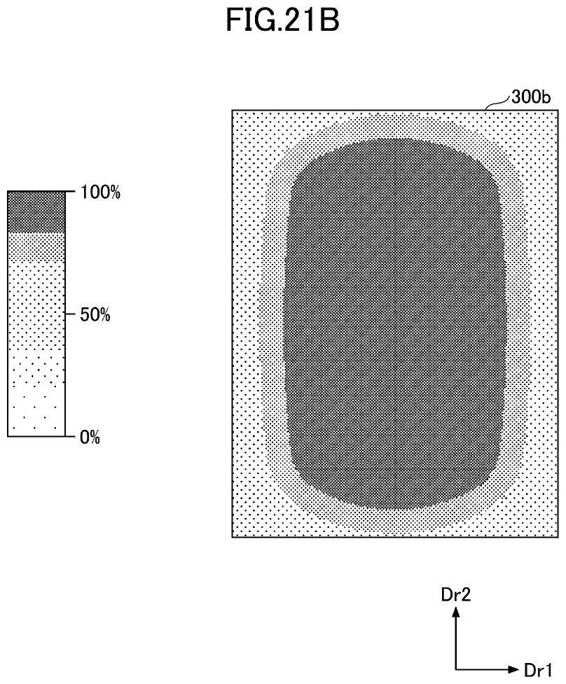

Subsequently, FIG. 20A illustrates an example of a simulation result of an illuminance distribution of first irradiation light 300a′ in a case in which no first lens 6a is provided in the first light source structure 7a (in other words, the first light emitting part 4a). FIG. 20A illustrates the first irradiation light 300a′ from one light emitting part 4 among the plurality of light emitting parts 4. FIG. 20B illustrates an example of a simulation of the illuminance distribution of second irradiation light 300b′ in a case in which no second lens 6b is provided in the second light source structure 7b (in other words, the second light emitting part 4b). FIG. 20B illustrates the second irradiation light 300b′ from one light emitting part 4 among the plurality of light emitting parts 4. FIG. 21A illustrates an example of a simulation result of the illuminance distribution of the first irradiation light 300a of the first light source structure 7a (in other words, a structure of the first light emitting part 4a and the first lens 6a). FIG. 21A illustrates the first irradiation light 300a from one first light source structure 7a among the plurality of first light source structures 7a. FIG. 21B illustrates an example of a simulation result of the illuminance distribution of the second irradiation light 300b of the second light source structure 7b (in other words, a structure of the second light emitting part 4b and the second lens 6b). FIG. 21B illustrates the second irradiation light 300b from one second light source structure 7b among the plurality of second light source structures 7b.

FIGS. 20A and 21A illustrate the illuminance distributions of the first irradiation light 300a′ and the first irradiation light 300a emitted to an irradiation surface when viewed from a normal direction of the irradiation surface. FIGS. 20B and 21B illustrate the illuminance distributions of the second irradiation light 300b′ and the second irradiation light 300b emitted to an irradiation surface when viewed from a normal direction of the irradiation surface. The first irradiation light 300a', the first irradiation light 300a, the second irradiation light 300b', and the second irradiation light 300b represent their respective illuminance distributions on rectangular irradiation target surfaces (for example, camera's angle of views) having equal areas in a plan view. FIGS. 20A, 20B, 21A, and 21B are contour plots, each of which indicates the level of illuminance in association with the type of dot hatching. The level of illuminance is a relative illuminance where the highest illuminance obtained in the irradiated area is 100%, and the lowest illuminance obtained therein is 0%. A region indicated by a predetermined type of dot hatching is a region where a predetermined range of illuminance is obtained.

As illustrated in FIGS. 20A and 20B, the first irradiation light 300a′ and the second irradiation light 300b′ both represent a region having a substantially circular shape when viewed from the normal direction of the irradiation surface, in which the illuminance is high in the region near the center of the irradiation surface. The illuminance is relatively low in the region outside the substantially circular region. As illustrated in FIGS. 21A and 21B, the first irradiation light 300a and the second irradiation light 300b both represent a region having a substantially rectangular shape which is nearly similar to the rectangular shape of the irradiation surface in a plan view, in which the illuminance is high in the region near the center of the irradiation surface. The illuminance is relatively low in the region outside the substantially rectangular region. Areas of the regions having a low illuminance in the first irradiation light 300a and the second irradiation light 300b are smaller than areas of the regions having a low illuminance in the first irradiation light 300a′ and the second irradiation light 300b'. Therefore, it can be found that the first irradiation light 300a and the second irradiation light 300b have the light distribution characteristics with reduced unevenness in illuminance, compared to the first irradiation light 300a′ and the second irradiation light 300b'.

The first light source structure 7a and the second light source structure 7b further include the first lens 6a and the second lens 6b, respectively, on the light emission surface 43 of the first light emitting part 4a and the second light emitting part 4b, respectively, whereby the brightness necessary for illumination for shooting can be ensured, while the unevenness in illuminance on the irradiation surfaces irradiated by the first light source structure 7a and the second light source structure 7b, respectively, can be reduced.

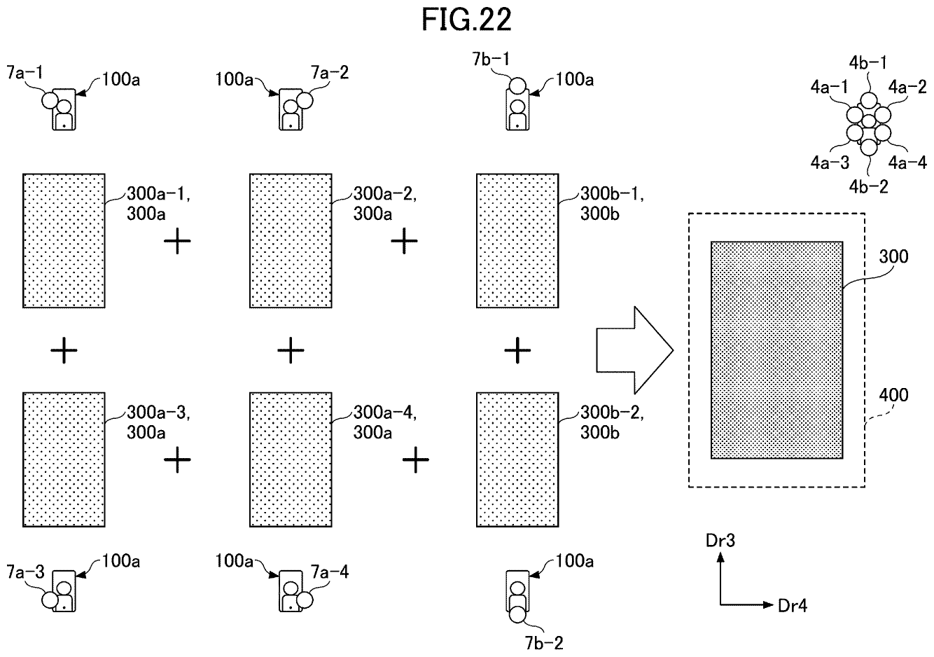

Subsequently, FIG. 22 schematically illustrates irradiation light 300 obtained by combining the first irradiation light 300a from each of the plurality of first light source structures 7a and the second irradiation light 300b from each of the plurality of second light source structures 7b in the image display device 100a. The “+” marks in FIG. 22 indicate combining irradiation light.

In FIG. 22, when the case is described as an example in which two first light source structures 7a are arranged on each of the pair of long lateral surfaces 11a, and one second light source structure 7b is arranged on each of the pair of short lateral surfaces 11b, first irradiation light 300a-1 is the light emitted from a first light source structure 7a-1 in the image display device 100a to the irradiation surface. First irradiation light 300a-2 is the light emitted to the irradiation surface from a first light source structure 7a-2 in the image display device 100a. Second irradiation light 300b-1 is the light emitted to the irradiation surface from a second light source structure 7b-1 in the image display device 100a. First irradiation light 300a-3 is the light emitted to the irradiation surface from a first light source structure 7a-3 in the image display device 100a. First irradiation light 300a-4 is the light emitted to the irradiation surface from a first light source structure 7a-4 in the image display device 100a. Second irradiation light 300b-2 is the light emitted to the irradiation surface from a second light source structure 7b-2 in the image display device 100a.

As illustrated in FIG. 22, each of the first irradiation light 300a-1, the first irradiation light 300a-2, the first irradiation light 300a-3, and the first irradiation light 300a-4 has substantially the same shape and same size. The second irradiation light 300b-1 and the second irradiation light 300b-2 have substantially the same shape and same size. The longitudinal directions thereof are substantially parallel to each other.

The irradiation light 300 is the light obtained on an irradiation surface 400 when irradiated with light in parallel from each of the first light source structure 7a-1, the first light source structure 7a-2, the first light source structure 7a-3, the first light source structure 7a-4, the second light source structure 7b-1, and the second light source structure 7b-2. The first irradiation light 300a-1, the first irradiation light 300a-2, the second irradiation light 300b-1, the first irradiation light 300a-3, the first irradiation light 300a-4 and the second irradiation light 300b-2 are combined while being almost superimposed on one another on the irradiation surface 400. This makes the illuminance of the irradiation light 300 higher than the illuminance of, for example, one first irradiation light 300a-1 obtained by one first light source structure 7a-1. Since the amount of irradiation light required for one light source structure 7 can be reduced as the number of the light source structures 7 increases, the area of the light-emitting surface of the light-emitting element 402 of each light source structure 7 can be reduced relative to the case of a fewer number of the light source structures 7. For any one lens 6, as the area of the light-emitting surface of the light-emitting element 402 is reduced, the area of the lens 6 increases relative to the area of the light-emitting surface of the light-emitting element 402. In the light source structure 7, as the area of the lens 6 increases relative to the area of the light-emitting surface of the light-emitting element 402 in a plan view, it is easier to control the light distribution. Therefore, the image display device 100 and the smartphone 200 with more light source structures 7 mounted therein can emit adequate light with less unevenness in illuminance than the case of a fewer number of the light source structures 7. The irradiation light 300 made up of the first irradiation light 300a emitted from the four first light source structures 7a and the second irradiation light 300b emitted from the two second light source structures 7b has light distribution characteristics longer in the third direction Dr3 than in the fourth direction Dr4 on the irradiation surface 400.

### Effects of Image Display Device 100a and Smartphone 200a

In the present embodiment, as illustrated in FIGS. 12 to 17, each of the light emitting parts 4 further includes at least one lens 6 disposed to face the light emission surface 43. This allows the image display device 100a to add the lens characteristics of the lens 6 to the control factors of the light distribution of the light emitted from the image display device 100a, thereby facilitating the light distribution control. For example, the image display device 100a can generate the light distribution with reduced unevenness in illuminance.

The image display device 100a includes the first lens 6a and the second lens 6b both including the Fresnel lens surface. This allows the image display device 100a to efficiently collect light emitted from the light emitting part 4, whereby the image display device 100a can improve the light utilization efficiency. When each of the first lens 6a and the second lens 6b includes the lens surface including the total reflection portion, or when the first lens 6a and the second lens 6b respectively include the Fresnel lens surface and the lens surface including the total reflection portion, or respectively include the lens surface including the total reflection portion and the Fresnel lens surface, the image display device 100a can also achieve nearly the same effects as those described above.

The first lens 6a includes the first surface 61a facing the light emission surface 43, and the second surface 62a located on the opposite side to the first surface 61a. The first surface 61a is the lens surface having a curvature only in the first direction Dr1. The second surface 62a is the lens surface having a curvature only in the second direction Dr2. With these configurations, the first lens 6a can emit light having a rectangular shape in a plan view. Since an image captured by the imaging device 5 has a rectangular shape, the first lens 6a emits light having the rectangular shape in a plan view, and can thus efficiently irradiate the region corresponding to the shape of the captured image with the light. The second lens 6b includes the first surface 61b facing the light emission surface 43, and the second surface 62b located on the opposite side to the first surface 61b. The first surface 61b is the lens surface having a curvature only in the second direction Dr2. The second surface 62b is the lens surface having a curvature only in the first direction Dr1. With these configurations, the second lens 6b can emit light having the rectangular shape in a plan view rotated by substantially 90°with respect to the irradiation light from the first lens 6 a described above, and can thus achieve nearly the same effects as the first lens 6a.

In the first lens 6a, the first surface 61a is the Fresnel lens surface, and the second surface 62a is the cylindrical lens surface. One surface of the first lens 6a is provided as the Fresnel lens surface, so that the range of curvature that can be generated by the lens surface can be widened as compared with the case in which a non-Fresnel lens surface is used. This facilitates the control of distribution of light emitted from the image display device 100a.

One surface of the first lens 6a is provided as the cylindrical lens surface, so that the lens surface can be formed more easily as compared with the case in which the non-cylindrical lens surface is used. In the second lens 6b, the first surface 61b is the Fresnel lens surface, and the second surface 62b is the cylindrical lens surface. With this configuration, the second lens 6b can achieve nearly the same effect as the first lens 6a described above.

As in the present embodiment, when the first surface 61a and the first surface 61b are the Fresnel lens surfaces, the plurality of convex portions protrude toward the light emission surface 43. This prevents damage to the Fresnel lens surface during assembly of the image display device 100a and facilitates assembly of the image display device 100a.

The one or more light emitting parts 4 included in the image display device 100a are a plurality of light emitting parts 4. The plurality of light emitting parts 4 include one or more first light emitting parts 4a and one or more second light emitting parts 4b. The one or more lenses 6 included in the image display device 100a consist of a plurality of lenses 6.

The plurality of lenses 6 include the first lens 6a disposed on the first light emitting part 4a and the second lens 6b disposed on the second light emitting part 4b. The first light emitting part 4a and the first lens 6a constitute the first light source structure 7a. The second light emitting part 4b and the second lens 6b constitute the second light source structure 7b. The first light source structure 7a and the second light source structure 7b have the light distribution characteristics different from each other. In the image display device 100a, the first irradiation light 300a from the first light source structure 7a and the second irradiation light 300b from the second light source structure 7b are at least partially superimposed on one another on the irradiation surface, thereby increasing the illuminance of the irradiation light from the image display device 100a. The light distribution characteristics of the first light source structure 7a and the second light source structure 7b different from each other, so that it is possible to reduce the difference between the shape of the first irradiation light 300a (see FIG. 18) from the first light source structure 7a in a plan view, and the shape of the second irradiation light 300b (see FIG. 19) from the second light source structure 7b in a plan view in accordance with the positions at which the first light source structure 7a and the second light source structure 7b are disposed. This allows the image display device 100a to align and superimpose the first irradiation light 300a and the second irradiation light 300b on one another on the irradiation surface, thereby increasing the illumination of the irradiation light from the image display device 100a.

In a plan view, the inner lateral surfaces 11 of the housing 1 of the image display device 100a are in a rectangular shape including the pair of the long lateral surfaces 11a extending in the third direction Dr3, and the pair of the short lateral surfaces 11b extending in the fourth direction Dr4 orthogonal to the third direction Dr3. The at least one first light source structure 7a is disposed along the long lateral surface 11a. The at least one second light source structure 7b is disposed along the short lateral surface. With these configurations, in the image display device 100a, the first light source structure 7a and the second light source structure 7b are disposed in a wide range on the inner lateral surfaces 11 of the housing 1, and the first irradiation light 300a and the second irradiation light 300b can be aligned and superimposed on one another on the irradiation surface.

The first lens 6a of the first light source structure 7a has the rectangular shape having the long sides and the short sides in a plan view, and includes the first surface 61a (corresponding to the third surface) facing the light emission surface 43 and the second surface 62a (corresponding to the fourth surface). The first surface 61a is the Fresnel lens surface having a curvature only in the long-side direction. The second surface 62a is the cylindrical lens surface having a curvature only in the short-side direction. The first light source structure 7a is disposed such that the long sides of the first lens 6a extend along the third direction Dr3. With these configurations, the image display device 100a can irradiate the irradiation surface (for example, within the camera's angle of view) with the first irradiation light 300a having the reduced unevenness in illuminance, while the first light source structure 7a is disposed on the inner lateral surface 11 of the housing 1.

The second lens 6b of the second light source structure 7b has the rectangular shape having the long sides and the short sides in a plan view, and includes the first surface 61b (corresponding to the fifth surface) facing the light emission surface 43 and the second surface 62b (corresponding to the sixth surface). The first surface 61b is the Fresnel lens surface having the curvature only in the short-side direction. The second surface 62b is the cylindrical lens surface having the curvature only in the long-side direction. The second light source structure 7b is disposed such that the long sides of the second lens 6b extend along the fourth direction Dr4. With these configurations, the image display device 100a can irradiate the irradiation surface (for example, within the camera angle of view) with the second irradiation light 300b having the reduced unevenness in illuminance, while the second light source structure 7b is disposed on the inner lateral surface 11 of the housing 1.

As illustrated in FIG. 22, the irradiation light 300 made up of the first irradiation light 300a emitted from at least one first light source structure 7a and the second irradiation light 300b emitted from at least one second light source structure 7b has light distribution characteristics longer in the third direction Dr3 than in the fourth direction Dr4 on the irradiation surface 400. An image captured by the imaging device 5 has a rectangular shape which is longer in the third direction Dr3 than in the fourth direction Dr4. Therefore, when the image display device 100a emits the irradiation light 300 having the light distribution characteristics longer in the third direction Dr3 than in the fourth direction Dr4, and thus can efficiently irradiate the region corresponding to the shape of the captured image with the light.

The light emitting part 4 includes the light-emitting element 402 and the light reflective member 404 covering the lateral surface of the light-emitting element 402. The light emitting part 4 and the first lens 6a or the second lens 6b have the rectangular shape elongated in the first direction Dr1 in a plan view. The width of the light-emitting element 402 in the first direction Dr1 is preferably in a range from 1/10 to 9/10 of the width of the first lens 6a or the second lens 6b in the first direction Dr1. This allows, in the image display device 100a, the light-emitting element 402 to emit the necessary and sufficient amount of light, and control the distribution of light by the lens 6 including the first lens 6a or the second lens 6b to reduce the unevenness in illuminance. Therefore, the image display device 100a can irradiate the irradiation surface with bright light while reducing glare.

In the second embodiment, the mode has been described as an example in which the light source structure 7 including at least one first light source structure 7a and at least one second light source structure 7b is disposed between the inner lateral surfaces 11 of the housing 1 and the lateral surfaces 22 of the display unit 2. The mode is not limited to this, and the light source structure 7 and the light emitting part 4 may be provided together between the inner lateral surface 11 of the housing 1 and the lateral surface 22 of the display unit 2.

As illustrated in FIG. 11, in the image display device 100a, the inner lateral surfaces 11 of the housing 1 include the curved surface 13 between the long lateral surface 11a and the short lateral surface 11b in a plan view. The first light source structure 7a and the second light source structure 7b are not disposed on the curved surface 13. The first light source structure 7a and the second light source structure 7b are not disposed on the curved surface 13, so that the present embodiment can reduce the complexity of assembly of the image display device 100a and makes the assembly easier.

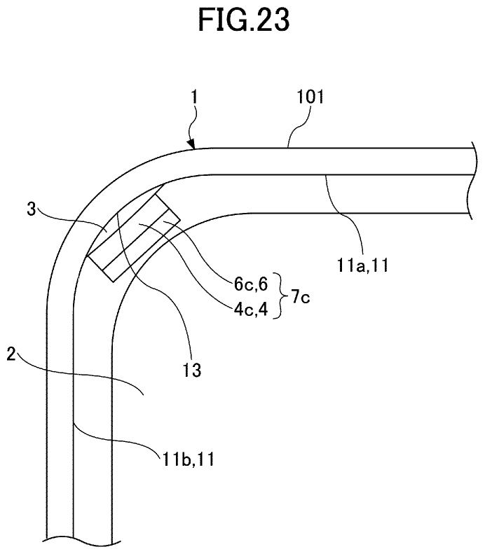

However, in the present embodiment, the light source structure including the light emitting part 4 and the lens 6 or the light emitting part 4 may be disposed on the curved surface 13. FIG. 23 illustrates a configuration example in which the light source structure is disposed on the curved surface 13 of the housing 1. FIG. 23 is an enlarged view of the curved surface 13 of the housing 1 and its vicinity.

As illustrated in FIG. 23, the one or more light emitting parts 4 include one or more third light emitting parts 4c. The at least one lens 6 includes a third lens 6c disposed on the third light emitting part 4c. The third light emitting part 4c is mounted with a bonding member such as solder so as to be electrically connected to the wiring substrate 3 bonded to the curved surface 13 with an adhesive member or the like. The third light emitting part 4c and the third lens 6c constitute a third light source structure 7c. In the image display device 100a, the inner lateral surfaces 11 of the housing 1 may include the curved surface 13 between the long lateral surface 11a and the short lateral surface 11b in a plan view, and the third light source structure 7c may be provided on the curved surface 13. In the present embodiment, the light distribution characteristics of the third light source structure 7c are different from the light distribution characteristics of the first light source structure 7a and the light distribution characteristics of the second light source structure 7b. Without being limited to the third light source structure 7c, only the third light emitting part 4c may be disposed on the curved surface 13. The light distribution characteristics of the third light source structure 7c may be the same as the light distribution characteristics of the first light source structure 7a or the light distribution characteristics of the second light source structure 7b.

In the case of disposing electronic components or members in the housing of the smartphone, it is difficult to dispose the electronic components or members along the curved surface of the housing of the smartphone, so that a space where no electronic component or member is disposed may be generated in the vicinity of the curved surface. Disposing the third light source structure 7c or the third light emitting part 4c described above in such a space can achieve effective utilization of the space in the smartphone.

The effects of the second embodiment other than those described above are nearly the same as those of the first embodiment.

While preferred embodiments have been described in detail above, the disclosure is not limited to the above-described embodiments, various modifications and substitutions can be made to the above-described embodiments without departing from the scope described in the claims.

The ordinal numbers, quantity, and the like used in the description of the embodiments are all exemplified to specifically describe the technology of the present disclosure, and the present disclosure is not limited to the numbers exemplified. In addition, the connection relationship between the components is exemplified to specifically describe the technique of the present disclosure, and the connection relationship for implementing the function of the present disclosure is not limited thereto.

The image display device of the present disclosure includes the light emitting part that is mounted on the inner lateral surface of the housing, and can emit light in the direction in which the display surface of the display unit disposed inside the housing faces, and thus can be used in applications such as in image display devices, lighting, and vehicles.

Specifically, the image display device can be suitably used in electronic devices such as smartphones, tablets, notebook personal computers (PCs), televisions, and displays. In particular, the image display device can be suitably used for shooting by the imaging device for selfies. However, the image display device of the present disclosure is not limited to these use applications.

The present disclosure includes, for example, following Aspects.

[Aspect 1] An image display device comprising: a housing having inner lateral surfaces and an opening defined by the inner lateral surfaces; a display unit disposed in the opening and located on an inner side relative to the inner lateral surfaces of the housing, the display unit comprising a display surface and a lateral surface connected to the display surface; one or more wiring substrates, each disposed on a corresponding one of the inner lateral surfaces of the housing and comprising wiring portions at least on a side opposite to a surface thereof facing the corresponding inner lateral surface; and one or more light emitting parts, each disposed between a corresponding one of the inner lateral surfaces of the housing and a corresponding one of the lateral surfaces of the display unit and each disposed on corresponding ones of the wiring portions, wherein each of the one or more light emitting parts comprises: a mounting surface facing the wiring portions of the corresponding wiring substrate, and a light emission surface meeting and connected to the mounting surface, and the one or more light emitting parts are configured to emit light in a direction in which the display surface faces.

[Aspect 2] The image display device according to Aspect 1, wherein the wiring substrate is a flexible substrate.

[Aspect 3] The image display device according to Aspect 1 or 2 wherein each of the one or more light emitting parts further comprises at least one lens disposed to face the light emission surface.

[Aspect 4] The image display device according to Aspect 3, wherein the at least one lens has at least one of a Fresnel lens surface or a lens surface comprising a total reflection portion.

[Aspect 5] The image display device according to Aspect 3 or 4, wherein the at least one lens has a first surface facing the light emission surface, and a second surface located on a side opposite to the first surface, one of the first surface and the second surface is a lens surface having a curvature only in a first direction, and the other of the first surface and the second surface is a lens surface having a curvature only in a second direction orthogonal to the first direction.

[Aspect 6] The image display device according to Aspect 5, wherein one of the first surface and the second surface is the Fresnel lens surface, and the other of the first surface and the second surface is a cylindrical lens surface.

[Aspect 7] The image display device according to any one of Aspects 3 to 6, wherein the one or more light emitting parts are a plurality of the light emitting parts, the plurality of the light emitting parts comprise one or more first light emitting parts and one or more second light emitting parts, the at least one lens comprises a first lens disposed on each of the first light emitting parts, and a second lens disposed on each of the second light emitting parts, the first light emitting part and the first lens constitute a first light source structure, the second light emitting part and the second lens constitute a second light source structure, and the first light source structure and the second light source structure have light distribution characteristics different from each other.

[Aspect 8] The image display device according to Aspect 7, wherein the inner lateral surfaces of the housing are in a rectangular shape having a pair of long lateral surfaces extending in a third direction and a pair of short lateral surfaces extending in a fourth direction orthogonal to the third direction in a plan view, at least one first light source structure of a plurality of the first light source structures is disposed along the long lateral surface, and at least one second light source structure of a plurality of the second light source structures is disposed along the short lateral surface.

[Aspect 9] The image display device according to Aspect 8, wherein the first lens of the first light source structure has a rectangular shape having long sides and short sides in a plan view, and has a third surface facing the light emission surface, and a fourth surface located on an opposite side to the third surface, one of the third surface and the fourth surface is the Fresnel lens surface having a curvature only in a long-side direction, the other of the third surface and the fourth surface is the cylindrical lens surface having a curvature only in a short-side direction, and the first light source structure is disposed such that the long side of the first lens extends along the third direction.

[Aspect 10] The image display device according to Aspect 8 or 9, wherein the second lens of the second light source structure has a rectangular shape having long sides and short sides in a plan view, and has a fifth surface facing the light emission surface, and a sixth surface located on a side opposite to the fifth surface, one of the fifth surface and the sixth surface is the Fresnel lens surface having a curvature only in a short-side direction, the other of the fifth surface and the sixth surface is the cylindrical lens surface having a curvature only in a long-side direction, and the second light source structure is disposed such that the long side of the second lens extends along the fourth direction.

[Aspect 11] The image display device according to Aspect 8, wherein the inner lateral surfaces of the housing include a curved surface between the long lateral surface and the short lateral surface in a plan view, and the first light source structure and the second light source structure are not disposed on the curved surface.

[Aspect 12] The image display device according to Aspect 8, wherein irradiation light made up of first irradiation light emitted from the at least one first light source structure, and second irradiation light emitted from the at least one second light source structure has light distribution characteristics longer in the third direction than in the fourth direction on an irradiation surface.

[Aspect 13] The image display device according to any one of Aspects 1 to 12, wherein the light emitting part comprises a light-emitting element, and a wavelength conversion layer disposed on the light-emitting element.

[Aspect 14] The image display device according to Aspect 5, wherein the light emitting part comprises a light-emitting element and a light reflective member covering a lateral surface of the light-emitting element, the light emitting part and the lens have a rectangular shape elongated in the first direction in a plan view, and a width of the light-emitting element in the first direction is in a range from 1/10 to 9/10 of a width of the lens in the first direction.

[Aspect 15] The image display device according to any one of Aspects 1 to 14, wherein the light emitting part comprises a light-emitting element, an area of a light-emitting surface of the light-emitting element is in a range from 0.02 mm² to 0.22 mm² in a plan view, and an electric current supplied to the light-emitting element is in a range from 0.05 mA to 5 mA.

[Aspect 16] The image display device according to Aspect 15, wherein the one or more light emitting parts are a plurality of the light emitting parts, each of the plurality of the light emitting parts comprises at least one light-emitting element, and the light-emitting element is controllable to be turned on individually or for each group.

[Aspect 17] The image display device according to any one of Aspects 1 to 14, wherein the light emitting part comprises a light-emitting element, a size of a light-emitting surface of the light-emitting element is in a range from 0.1 mm² to 2 mm² in a plan view, and an electric current supplied to the light-emitting element is in a range from 0.5 mA to 100 mA.

[Aspect 18] The image display device according to Aspect 17, wherein the light emitting part comprises two or more light-emitting elements, and the light-emitting elements are controllable to be turned on individually or for each group.

[Aspect 19] A smartphone comprising: the image display device according to any one of Aspects 1 to 18.

### REFERENCE CHARACTER LIST

1 Housing
11 Inner lateral surface
11a Long lateral surface
11b Short lateral surface
101 Outer lateral surface
12 Opening portion
13 Curved surface
2 Display unit
21 Display surface
22 Lateral surface
23 Person image
24 Capture button
3 Wiring substrate
31 First wiring surface
32 Second wiring surface
33 Wiring portion
34 Wiring
4 Light emitting part
4A, 4B, 4C Light emitting part group
4a First light emitting part
4b Second light emitting part
4c Third light emitting part
41 First main surface
42 Mounting surface
43 Light emission surface
43a Normal line
44 Second main surface
401 Substrate
402 Light-emitting element
403 Wavelength conversion layer
404 Light reflective member
405 First electrode
406 Second electrode
407 Conductive member
5 Imaging device
6 Lens
6a First lens
61a First surface
62a Second surface
6b Second lens
61b First surface
62b Second surface
6c Third lens
7 Light source structure
7a First light source structure
7b Second light source structure
7c Third light source structure
60 Cover plate
81 Left side button
82 Right side button
9 Connection interface
100, 100A, 100a Image display device
200, 200A, 200a Smartphone
300 Irradiation light
300a First irradiation light
300b Second irradiation light
400 Irradiation surface
Dr1 First direction
Dr2 Second direction
Dr3 Third direction
Dr4 Fourth direction

1. An image display device comprising:
a housing having inner lateral surfaces and an opening defined by the inner lateral surfaces;
a display unit disposed in the opening and located on an inner side relative to the inner lateral surfaces of the housing, the display unit comprising a display surface and a lateral surface connected to the display surface;
one or more wiring substrates, each disposed on a corresponding one of the inner lateral surfaces of the housing and comprising wiring portions at least on a side opposite to a surface thereof facing the corresponding inner lateral surface; and
one or more light emitting parts, each disposed between a corresponding one of the inner lateral surfaces of the housing and a corresponding one of the lateral surfaces of the display unit and each disposed on corresponding ones of the wiring portions, wherein:
each of the one or more light emitting parts comprises:
a mounting surface facing the wiring portions of the corresponding wiring substrate, and
a light emission surface meeting and connected to the mounting surface, and
the one or more light emitting parts are configured to emit light in a direction in which the display surface faces.

2. The image display device according to claim 1, wherein:
the wiring substrate is a flexible substrate.

3. The image display device according to claim 1, wherein:
each of the one or more light emitting parts further comprises at least one lens disposed to face the light emission surface.

4. The image display device according to claim 3, wherein:
the at least one lens has at least one of a Fresnel lens surface or a lens surface comprising a total reflection portion.

5. The image display device according to claim 3, wherein:
the at least one lens has a first surface facing the light emission surface, and a second surface located on a side opposite to the first surface,
one of the first surface and the second surface is a lens surface having a curvature only in a first direction, and
the other of the first surface and the second surface is a lens surface having a curvature only in a second direction orthogonal to the first direction.

6. The image display device according to claim 5, wherein:
one of the first surface and the second surface is the Fresnel lens surface, and
the other of the first surface and the second surface is a cylindrical lens surface.

7. The image display device according to claim 3, wherein:
the one or more light emitting parts are a plurality of the light emitting parts,
the plurality of the light emitting parts comprise one or more first light emitting parts and one or more second light emitting parts,
the at least one lens comprises:
a first lens disposed on each of the first light emitting parts, and
a second lens disposed on each of the second light emitting parts,
the first light emitting part and the first lens constitute a first light source structure,
the second light emitting part and the second lens constitute a second light source structure, and
the first light source structure and the second light source structure have light distribution characteristics different from each other.

8. The image display device according to claim 7, wherein:
the inner lateral surfaces of the housing are in a rectangular shape having a pair of long lateral surfaces extending in a third direction and a pair of short lateral surfaces extending in a fourth direction orthogonal to the third direction in a plan view,
at least one first light source structure of a plurality of the first light source structures is disposed along the long lateral surface, and
at least one second light source structure of a plurality of the second light source structures is disposed along the short lateral surface.

9. The image display device according to claim 8, wherein:
the first lens of the first light source structure has a rectangular shape having long sides and short sides in a plan view, and has a third surface facing the light emission surface, and a fourth surface located on an opposite side to the third surface,
one of the third surface and the fourth surface is the Fresnel lens surface having a curvature only in a long-side direction,
the other of the third surface and the fourth surface is the cylindrical lens surface having a curvature only in a short-side direction, and
the first light source structure is disposed such that the long side of the first lens extends along the third direction.

10. The image display device according to claim 8, wherein:
the second lens of the second light source structure has a rectangular shape having long sides and short sides in a plan view, and has a fifth surface facing the light emission surface, and a sixth surface located on a side opposite to the fifth surface,
one of the fifth surface and the sixth surface is the Fresnel lens surface having a curvature only in a short-side direction,
the other of the fifth surface and the sixth surface is the cylindrical lens surface having a curvature only in a long-side direction, and
the second light source structure is disposed such that the long side of the second lens extends along the fourth direction.

11. The image display device according to claim 8, wherein:
the inner lateral surfaces of the housing include a curved surface between the long lateral surface and the short lateral surface in a plan view, and
the first light source structure and the second light source structure are not disposed on the curved surface.

12. The image display device according to claim 8, wherein:
irradiation light made up of first irradiation light emitted from the at least one first light source structure, and second irradiation light emitted from the at least one second light source structure has light distribution characteristics longer in the third direction than in the fourth direction on an irradiation surface.

13. The image display device according to claim 1, wherein:
the light emitting part comprises a light-emitting element, and a wavelength conversion layer disposed on the light-emitting element.

14. The image display device according to claim 5, wherein:
the light emitting part comprises a light-emitting element, and a light reflective member covering a lateral surface of the light-emitting element,
the light emitting part and the lens have a rectangular shape elongated in the first direction in a plan view, and
a width of the light-emitting element in the first direction is in a range from 1/10 to 9/10 of a width of the lens in the first direction.

15. The image display device according to claim 1, wherein:
the light emitting part comprises a light-emitting element,
an area of a light-emitting surface of the light-emitting element is in a range from 0.02 mm² to 0.22 mm² in a plan view, and
an electric current supplied to the light-emitting element is in a range from 0.05 mA to 5 mA.

16. The image display device according to claim 15, wherein:
the one or more light emitting parts are a plurality of the light emitting parts,
each of the plurality of the light emitting parts comprises at least one light-emitting element, and
the light-emitting element is controllable to be turned on individually or for each group.

17. The image display device according to claim 1, wherein:
the light emitting part comprises a light-emitting element,
a size of a light-emitting surface of the light-emitting element is in a range from 0.1 mm² to 2 mm² in a plan view, and
an electric current supplied to the light-emitting element is in a range from 0.5 mA to 100 mA.

18. The image display device according to claim 17, wherein:
the light emitting part comprises two or more light-emitting elements, and
the light-emitting elements are controllable to be turned on individually or for each group.

19. A smartphone comprising:
the image display device according to claim 1.
